(19) United States
(12) Patent Application Publication
(10) Pub. No.: US 2025/0366201 A1
(43) Pub. Date: Nov. 27, 2025

(54) SEMICONDUCTOR STRUCTURES HAVING DUMMY REGIONS

(71) Applicant: Taiwan Semiconductor Manufacturing Company, Ltd., Hsin-Chu (TW)

(72) Inventors: Yi-Hui Chen, Changhua County (TW); Yi-Lii Huang, Hsinchu County (TW); Chih-Hsiao Chen, Taichung City (TW); Hui-Hsuan Kung, Taichung City (TW); Yi-Chen Li, Taichung City (TW); Yen Wei Tseng, Hsinchu County (TW)

(21) Appl. No.: 18/891,548

(22) Filed: Sep. 20, 2024

Related U.S. Application Data
(60) Provisional application No. 63/651,546, filed on May 24, 2024.

(51) Int. Cl. H01L 27/118; H10B 10/00

(52) U.S. Cl. CPC H10D 84/907; H10B 10/125; H10D 84/953; H10D 84/974

(57) ABSTRACT

A semiconductor structure and a method of fabricating thereof including a substrate having a device region and a dummy region. The device region includes a number of N-type device cells having a plurality of operational N-type transistors and a number of P-type device cells having a plurality of operational P-type transistors. The dummy region includes a number of N-type dummy cells having a plurality of non-operational N-type transistors and a number of P-type dummy cells having a plurality of non-operational P-type transistors, and a total number of the N-type device cells and P-type device cells is equal to a total number of the N-type dummy cells and P-type dummy cells.

### PRIORITY DATA

The present application claims priority to provisional application No. 63/651,546, filed May 24, 2024, which is hereby incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

Such scaling down has also increased the complexity of processing and manufacturing ICs. For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. Planar transistors may also be implemented for various performance considerations.

While existing technologies for fabricating semiconductor structures including device regions and dummy regions are generally adequate for their intended purposes, they have not been entirely satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of an exemplary method for designing a layout, according to various aspects of the present disclosure.

FIGS. 2A and 2B are fragmentary plan view of an exemplary semiconductor structure, according to various aspects of the present disclosure.

FIG. 3A illustrates a fragmentary layout pattern of a sub-region of the exemplary semiconductor structure, according to various aspects of the present disclosure.

FIG. 3B illustrates an enlarged portion of the sub-region of the exemplary semiconductor structure, according to various aspects of the present disclosure.

FIG. 4A illustrates a fragmentary cross-sectional view of the enlarged portion taken along line A-A shown in FIG. 3B, according to various aspects of the present disclosure.

FIG. 4B illustrates a fragmentary cross-sectional view of the enlarged portion taken along line B-B shown in FIG. 3B, according to various aspects of the present disclosure.

FIG. 4C illustrates a fragmentary cross-sectional view of the enlarged portion taken along line C-C shown in FIG. 3B, according to various aspects of the present disclosure.

FIG. 4D illustrates a fragmentary cross-sectional view of the enlarged portion taken along line D-D shown in FIG. 3B, according to various aspects of the present disclosure.

FIG. 4E illustrates a fragmentary cross-sectional view of the enlarged portion taken along line E-E shown in FIG. 3B, according to various aspects of the present disclosure.

FIGS. 5A, 5B, 5C, 5D, and 5E illustrate fragmentary alternative layout patterns of the sub-region of the exemplary semiconductor structure, according to a first alternative embodiment the present disclosure.

FIGS. 6A, 6B, 6C, 6D, 6E and 6F illustrate fragmentary alternative layout patterns of the sub-region of the exemplary semiconductor structure, according to a second alternative embodiment of the present disclosure.

FIGS. 7A, 7B, 7C, 7D, 7E and 7F illustrate fragmentary alternative layout patterns of the sub-region of the exemplary semiconductor structure, according to a third alternative embodiment of the present disclosure.

FIGS. 8A, 8B, 8C, 8D, 8E and 8F illustrate fragmentary alternative layout patterns of the sub-region of the exemplary semiconductor structure, according to a fourth alternative embodiment of the present disclosure.

FIGS. 9A, 9B, 9C, 9D, 9E and 9F illustrate fragmentary alternative layout patterns of the sub-region of the exemplary semiconductor structure, according to a fifth alternative embodiment of the present disclosure.

FIGS. 10A, 10B and 10C illustrate fragmentary alternative layout patterns of the sub-region of the exemplary semiconductor structure, according to a sixth alternative embodiment of the present disclosure.

FIG. 11 illustrates a fragmentary alternative layout pattern of the sub-region of the exemplary semiconductor structure, according to a seventh alternative embodiment of the present disclosure.

FIG. 12 illustrates a fragmentary alternative layout pattern of the sub-region of the exemplary semiconductor structure, according to an eighth alternative embodiment of the present disclosure.

FIG. 13 is a flow chart of an exemplary method for fabricating a semiconductor structure, according to various aspects of the present disclosure.

FIGS. 14A, 15A, 16A, 17A, 18A, 19A, 20A illustrate fragmentary cross-sectional views of the semiconductor structure taken along line C-C′ as shown in FIG. 3B during various fabrication stages in the method of FIG. 13, according to various aspects of the present disclosure.

FIGS. 14B, 15B, 16B, 17B, 18B, 19B, 20B illustrate fragmentary cross-sectional views of the semiconductor structure taken along line E-E as shown in FIG. 3B during various fabrication stages in the method of FIG. 13, according to various aspects of the present disclosure.

FIGS. 14C, 15C, 16C, 17C, 18C, 19C, 20C illustrate fragmentary cross-sectional views of the semiconductor structure taken along line D-D′ as shown in FIG. 3B during various fabrication stages in the method of FIG. 13, according to various aspects of the present disclosure.

FIG. 21 is a block diagram of a system for implementing one or more aspects of the present disclosure including the method of FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

In forming a semiconductor structure such as a semiconductor chip, active semiconductor devices such as transistors are formed on a substrate. The transistors may be planar transistors or advanced transistors, such as fin-type field effect transistors (FinFETs) or gate-all-around (GAA) transistors. The transistors may be a part of an integrated circuits (IC). The transistors fabricated on the substrate may be p-type transistors or n-type transistors. P-type transistors may be P-type metal-oxide-semiconductor (PMOS) transistors (e.g., include p-type source/drain features). N-type transistors may be N-type metal-oxide-semiconductor (NMOS) transistors (e.g., an n-type source/drain features). The PMOS and NMOS transistors are formed in device regions of the substrate. In particular, semiconductor structures include numerous active regions (or “oxide definitions” (ODs)) on which transistors are formed. The active region defines the area for each transistor; that is, the area where the transistor's source/drain features and channel regions are formed. The active region is defined between isolation regions such as provided by shallow trench isolation (STI) or field oxide (FOX) areas. The semiconductor devices such as the transistors discussed above are active devices, which in some cases along with passive devices, are formed on device regions of a substrate. The substrate also includes dummy regions, which may not include functional devices.

The semiconductor structures are formed beginning with a design process. Computer aided design/electronic design automation (CAD/EDA) tools allow for such designing semiconductor devices. In some implementations, the circuit design process begins with a specification, which describes the desired functionality of the semiconductor structure (e.g., integrated circuit) and may include a variety of performance requirements. Then, in a logic design phase, logical implementation of the semiconductor structure is described using one of several hardware description languages (e.g., Verilog or VHDL at the register transfer logic (RTL) level of abstraction). The EDA software tool may synthesize the abstract logic into a technology dependent netlist using a library. The output can also describe the behavior of the circuits on the chip, as well as the interconnections to inputs and outputs.

After the logic design phase, the design proceeds to a physical design phase. The physical design creates a semiconductor structure design (e.g., a chip design). The physical design includes various steps including floor planning, place and routing, layout versus schematic (LVS) and design rule check (DRC) determinations. After a design of a semiconductor structure such as an integrated circuit chip is completed, a file (e.g., graphic data system (GDS) file) including the layout of the semiconductor structure is generated. The information is then provided (e.g., taped-out) to a fabrication facility. Masks defining the layers of the layout are then fabricated and used to fabricate the semiconductor structure itself. The present disclosure includes features that maybe represented in the layout during the design process.

One consideration in the logic design phase and the physical design phase in particular is across-chip uniformity. Certain semiconductor fabrication processes used to fabricate the chip according to the design introduce physical variations across the structure. The physical variations can lead to electrical performance and reliability issues. And as such, dummy regions are provided in the semiconductor structure (e.g., chip) that includes the functional/operational device regions (e.g., comprising the active semiconductor devices such as transistor discussed above). The dummy regions (or “nonfunctional regions”) may include dummy transistors or components that do not provide an electrical functionality to the semiconductor structure (e.g., are not interconnected). The dummy regions may mitigate loading effects during patterning, etching, polishing, deposition, and/or other fabrication processes. The present disclosure provides for semiconductor structures, systems, and methods that define dummy regions. The present disclosure provides for design of dummy regions that may be formed on a substrate along with device regions.

In semiconductor structure design, a standard cell is a block of transistors that is repeated according to a set of design rules across a design layout. A standard cell may be used for different functions. For example, a standard cell may be a static random access memory (SRAM) cell or a logic cell for logic operations. A standard cell may include one or more p-type transistors and one or more n-type transistors. In some implementations, cells may also be formed that are dummy cells. The present disclosure includes dummy region layouts that may be provided as cells for implementing into a semiconductor structure as discussed below.

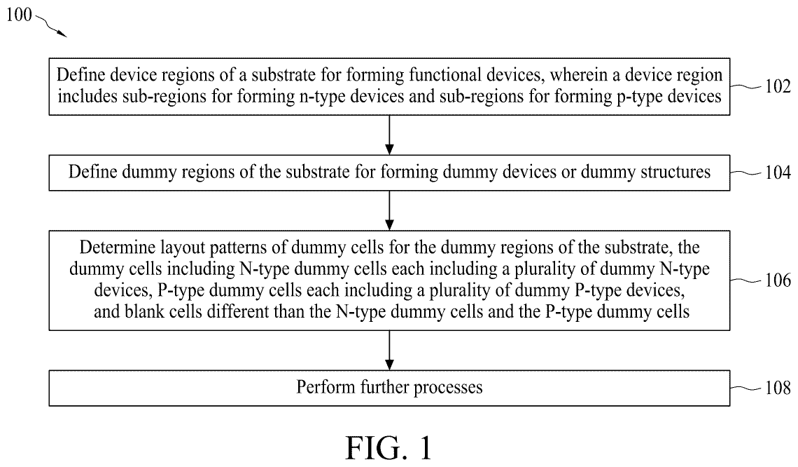

FIG. 1 illustrates a method 100 that may be implemented to form a semiconductor structure layout. In an embodiment, the semiconductor structure is a chip and in particular, an integrated circuit (IC) chip. The method 100 is merely exemplary and are not intended to limit the present disclosure to what is explicitly illustrated therein. Additional steps may be provided before, during and after the method 100, and some steps described can be replaced, eliminated, or moved around for additional embodiments of the methods. Not all steps are described herein in detail for reasons of simplicity.

With reference to FIGS. 1 and FIGS. 2A-3B, the method 100 includes a block 102 where, in a design process such as the physical design process discussed above, device regions 204A (or “functional regions 204A”) are identified on the layout for the semiconductor structure. The features of the semiconductor devices (e.g., gate structures) in the device regions 204A may be operational (e.g., contributing to the function of the device). The method 100 and block 102 may be used to define a layout of semiconductor devices including, but are not limited to, active and passive devices. Examples of active devices include transistors including, but are not limited to, metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), FinFETs, GAA devices, nanosheet transistors (including as illustrated below), planar MOS transistors including those with raised source/drain, or the like. Other active devices include diodes. Examples of passive elements include, but are not limited to, capacitors, inductors, fuses, resistors, or the like. The layout may include interconnection features coupling one or more of the active and passive devices together, and to an input/output terminal of the semiconductor structure.

In some embodiments, the device regions 204A of the substrate may be configured to form a memory structure including a number of SRAM cells. Each SRAM cell includes a number of N-type transistors and a number of P-type transistors. For example, a six-transistor SRAM cell includes 4 N-type transistors and 2 P-type transistors. Thus, for embodiments in which the device region 204A is a memory structure including a number of 6T SRAM cells, the total number of functional N-type transistors of the device region 204A may be greater than the total number of functional P-type transistors of the device region 204A. That is, the total number of N-type epitaxial source/drain features (NEPIs) of the device region 204A may be greater than a total number of P-type epitaxial source/drain features (PEPIs) of the device region 204A. In another instance, the device regions 204A may be configured to form a number of logic cells. For example, a NOR gate may include 2 N-type transistors and 2 P-type transistors. Thus, for forming logic cells, the total number of N-type epitaxial source/drain features (NEPIs) of the device region 204A may be equal to a total number of P-type epitaxial source/drain features (PEPIs) of the device region 204A. As a result, depending on various design requirements of the device region 204A, the total number of NEPIs of the device region 204A may be greater than, equal to, or less than the total number of PEPIs of the device region 204A. Sub-regions of the device regions 204A for forming functional N-type transistors including the NEPIs may be referred to as functional N-type cells, and sub-regions of the device regions 204A for forming functional P-type transistors including the PEPIs may be referred to as functional P-type cells. That is, the N-type cells are defined for N-type transistors, and the P-type cells are defined for P-type transistors. Depending on various design requirements of the device region 204A, the number of functional P-type cells of the device region 204A may be greater than, equal to, or less than the number of functional N-type cells of the device region 204A.

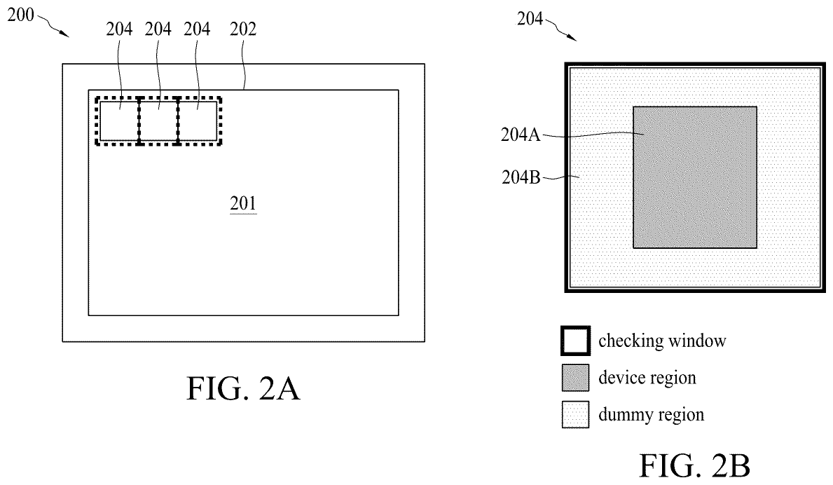

Still with reference to FIGS. 1 and FIGS. 2A-3B, the method 100 includes a block 104 where dummy regions 204B on the layout for the semiconductor structure are defined. Operations in block 104 may be performed concurrently with operations in block 102. The dummy region 204B may include devices or features that do not provide electrical functionality to the semiconductor structure (e.g., IC chip). In other words, the features (e.g., gate structures) or devices of the dummy region 204B may be non-operational and may be referred to as dummy features or dummy devices (e.g., dummy N-type transistors, dummy P-type transistors). The dummy region 204B may include structures that are realized using substantially the same manufacturing processes as those of the device region. The dummy region(s) 204B may be adjacent device regions 204A. For example, in the illustrated embodiment represented by FIG. 2B, when viewed from top, the dummy region 204B surrounds the device region 204A.

Still with reference to FIGS. 1 and FIGS. 2A-3B, the method 100 includes a block 106 where layout pattern of dummy region 204B is determined. In some embodiments, the dummy region 204B includes, for example, transistor features (e.g., channel regions, gate structures, NEPIs, PEPIs) that are substantially the same as those features forming the transistors of the device region 204A. In some further embodiments, the transistor features of the dummy region 204B are not connected (e.g., lack contacts) such that they are not interconnected with one another and/or with an input/output (I/O) of the semiconductor structure (e.g., IC chip).

In particular, in some implementations, operations in block 106 include defining certain sub-regions of the dummy region 204B that include dummy N-type transistors substantially similar to the functional n-type transistor in the device region 204A. In an embodiment, source/drain regions for forming the NEPIs (including both NEPIs in the device region 204A and NEPIs in the dummy region 204B) in fabrication of the chip are defined by a first masking element that provides both first openings in the device region 204A and second openings in the dummy region 204B concurrently. The first openings in the device region 204A allows for forming NEPIs of the functional n-type transistors and the second openings in the dummy region 204B allow for forming NEPIs of the dummy n-type transistors. The NEPIs are formed on the portions of active regions exposed by the first or second openings. In an embodiment, NEPIs in the dummy region 204B are substantially similar to and formed at the same time as the NEPIs in the device region 204A.

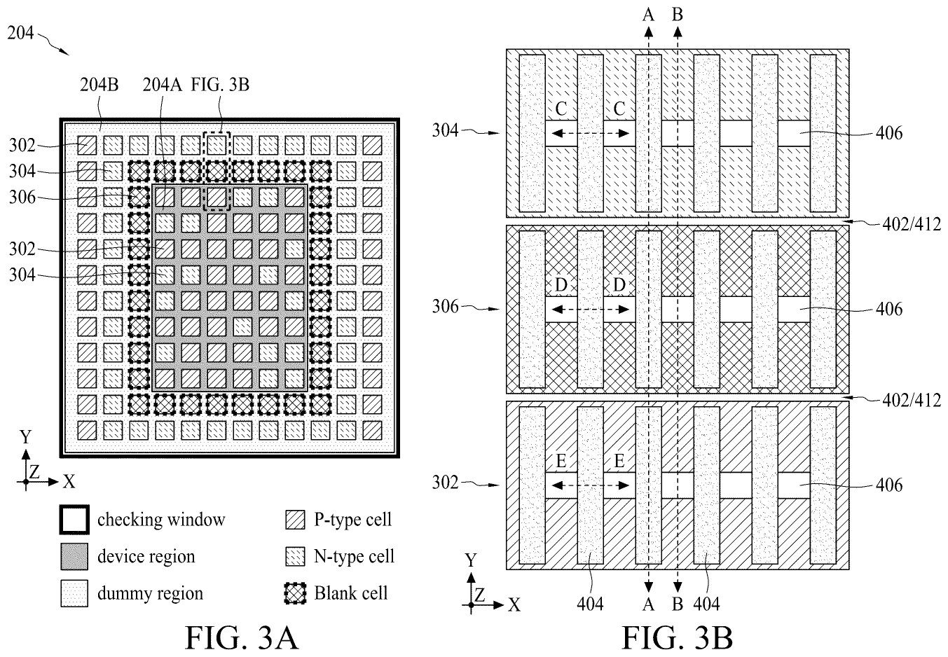

Operations in block 106 further include defining certain sub-regions of the dummy region 204B that include dummy P-type transistors substantially similar to the functional p-type transistor in the device region 204A. Sub-regions of the dummy regions 204B for forming dummy N-type transistors including NEPIs may be referred to as dummy N-type cells, and sub-regions of the dummy regions 204B for forming dummy P-type transistors including PEPIs may be referred to as dummy P-type cells. Source/drain regions for forming the PEPIs (including both PEPIs in the device region 204A and PEPIs in the dummy region 204B) in fabrication of the chip are defined by a second masking element that provides both third openings in the device region 204A and fourth openings in the dummy region 204B concurrently. The third openings in the device region 204A allows for forming PEPIs of the functional P-type transistors and the fourth openings in the dummy region 204B allow for forming PEPIs of the dummy P-type transistors. The PEPIs are formed on the portions of active regions exposed by the third openings or the fourth openings. In an embodiment, PEPIs in the dummy region 204B are substantially similar to and formed at the same time as the PEPIs in the device region 204A. In the present disclosure, the dummy N-type cells and the functional N-type cells may be substantially the same in terms of structure, the dummy N-type cells and the functional N-type cells may use the same reference numeral (e.g., 304 shown in FIG. 3A), the dummy P-type cells and the functional P-type cells may be substantially the same in terms of structure, the dummy P-type cells and the functional P-type cells may use the same reference numeral (e.g., 302 shown in FIG. 3A).

In the present disclosure, operations in block 106 include forming certain sub-regions for forming dummy structures including active regions and non-functional gate structures but do not including forming any of the NEPIs and PEPIs. Those sub-regions that are free of the NEPIs and PEPIs may be referred to as blank cells. Source/drain regions of active regions in the blank cells are not exposed by neither of the openings of the first masking element or the openings of the second masking element.

An open ratio of the first masking element providing the openings for forming NEPIs (or “NEPI openings”) affects the critical dimension (“CD”) of NEPIs. That is, a small open ratio for NEPIs (e.g., lower number of NEPIs) can provide for a larger NEPI CD. In some implementations, configurations (e.g., distributions, numbers) of NEPIs and PEPIs in the dummy region 204B allows for converging EPI critical dimension (CD) distribution between the devices of the semiconductor structure (e.g., chip).

Operations in block 106 further includes determining layout patterns of the dummy N-type cells, dummy P-type cells, and dummy blank cells such that a difference between an open ratio for NEPIs and an open ratio for PEPIs over an entirety of the device region 204A and the dummy region 204B may be reduced or even eliminated. In some implementations, the numbers and distributions of dummy N-type cells, dummy P-type cells and dummy blank cells in the dummy region 204B allows for converging EPI critical dimension (CD) distribution between the devices of the semiconductor structure (e.g., chip). The configuration of the layout pattern of the dummy region 204B including the location and quantity of dummy N-type cells, dummy P-type cells and blank cells is selectively determined based on the configuration of the device region 204A of block 102. In the present disclosure, a total number of dummy N-type cells in the dummy region 204B and functional N-type cells in the device region 204A is equal to a total number of dummy P-type cells in the dummy region 204B and functional P-type cells in the device region 204A. In an implementation, in the device region 204A, the number of functional N-type cells is the same as the number of functional P-type cells, and in the dummy region 204B, the number of dummy N-type cells is the same as the number of dummy P-type cells. In another implementations, in the device region 204A, the number of functional N-type cells is greater than the number of functional P-type cells, and in the dummy region 204B, the number of dummy N-type cells is less than the number of dummy P-type cells. In another implementation, in the device region 204A, the number of functional N-type cells is less than the number of functional P-type cells, and in the dummy region 204B, the number of dummy N-type cells is greater than the number of dummy P-type cells. For embodiments in which the locations and numbers of the functional N-type cells and functional P-type cells in the device region 204A are predetermined, the numbers of the dummy N-type cells and dummy P-type cells in the dummy region 204B may be flexibly arranged to achieve the above-mentioned converging EPI critical dimension (CD) distribution. In another embodiment, the number of blank cells in the dummy region 204B may be flexibly adjusted to enhance design flexibility, reduce defects in the device region 204A, and reduce cost for forming the NEPIs and PEPIs. In another embodiment, the locations of the dummy N-type cells and dummy P-type cells in the dummy region 204B may be flexibly arranged in the dummy region 204B may also be flexibly adjusted such that devices in the device region 204A may have less defects.

Method 100 further includes a block 108 where further processes are performed. Such further processes may include additional design processes such as design rule checks, tape-out of the layout, fabrication of photomasks according to the layout and fabrication of the semiconductor structure according to the photomasks. The fabricated semiconductor structure may include a dummy region having a plurality of N-type dummy cells having NEPIs and a plurality of P-type dummy cells having PEPIs, and in some implementations a plurality of blank cells that do not include NEPIs and PEPIs.

Referring to FIG. 2A, illustrated is a segment of a plan view of a semiconductor structure 200. The plan view includes a chip boundary region 202. The region between the edge of the semiconductor structure 200 and the chip boundary region 202 may provide an exclusion area, which may not include any active or passive semiconductor devices. The semiconductor structure 200 includes a number of sub-regions 204. The sub-regions 204 may be similar to one another. In an embodiment, various sub-regions 204 may patterned to include different features than one another. In an embodiment, the sub-regions 204 are formed by a same pattern. For reference purposes, the dashed line illustrates in an embodiment, a stepping field of a photolithography process. In some implementations, the stepper distance may be similar to the width of the sub-region 204 in the x-direction. In an embodiment, the sub-regions 204 define areas of, for example, approximately 18 μm by 18 μm in a fabricated device. Other suitable sizes are also possible. In some other implementations, the stepper distance may be half of the width of the sub-region 204 in the x-direction.

The sub-region 204 may include a device region 204A and a dummy region 204B as illustrated in FIG. 2B. The device region 204A may be defined as discussed above with reference to block 102 of the method 100. The dummy region 204B may be defined as discussed above with reference to blocks 104-106 of the method 100. Each of the device region 204A and the dummy region 204B include a plurality of active regions on which semiconductor devices such as transistors are formed. For example, gate structures and source/drain features may be formed on the active regions. The sub-region 204, and each of the device regions 204A and the dummy regions 204B, are not limited to the illustrated quadrangular top views, and for example, polygonal structures including triangular, pentagonal and octagonal structures and circular structures including an elliptical structure can be adopted without departing from the technical concept of the present invention.

The device region 204A may include functional n-type transistors, e.g., include NEPIs, channel regions and gate structures for functional n-type transistors, and functional p-type transistors, e.g., include PEPIs, channel regions, and gate structures for functional p-type transistors. The dummy regions 204B may include dummy n-type transistors, dummy p-type transistors, and blank cells. The dummy n-type transistors may be formed along with the functional n-type transistors, the dummy p-type transistors may be formed along with the functional p-type transistors. In some implementations, functional transistors in the device region 204A and dummy transistors in the dummy regions 204B are realized using substantially the same manufacturing processes and have substantially the same internal structure. The blank cells in the dummy region 204B may be realized using substantially the same manufacturing processes as the functional or dummy transistors, but have different internal structures. In some implementations, transistors formed in the dummy region 204B do not provide functionality to the formed structure (e.g., are not interconnected), while the transistors formed in the device region 204A are interconnected to form the IC functionality of the structure (e.g., chip).

When fabricated as semiconductor structure 200, a semiconductor substrate 201 is provided. In an embodiment, the substrate 201 includes silicon. Alternatively or additionally, the substrate 201 includes another elementary semiconductor, such as germanium; a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlInAs, AlGaAs, GaInAs, GaInP, and/or GaInAsP; or combinations thereof. Alternatively, the substrate 201 is a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, and/or other suitable methods.

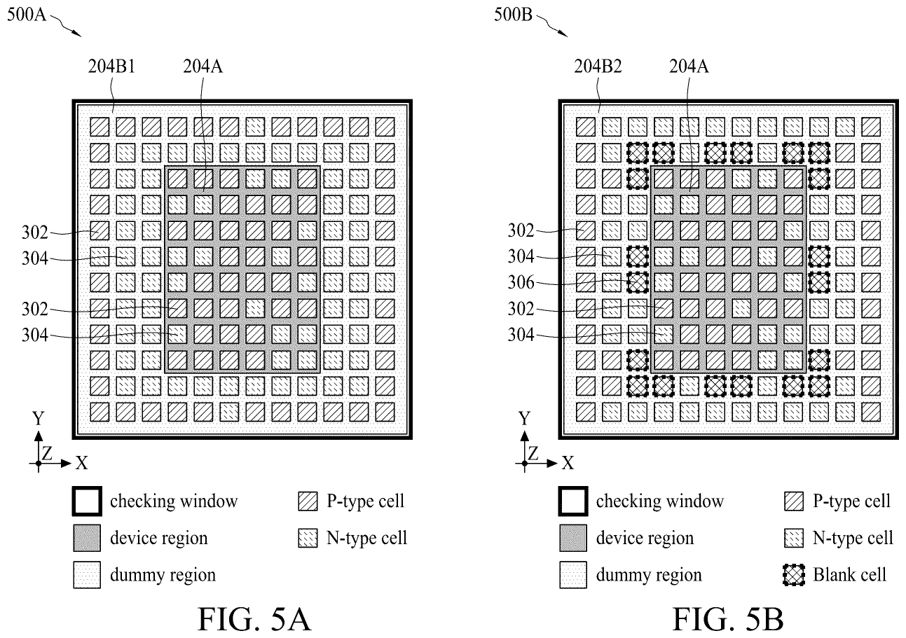

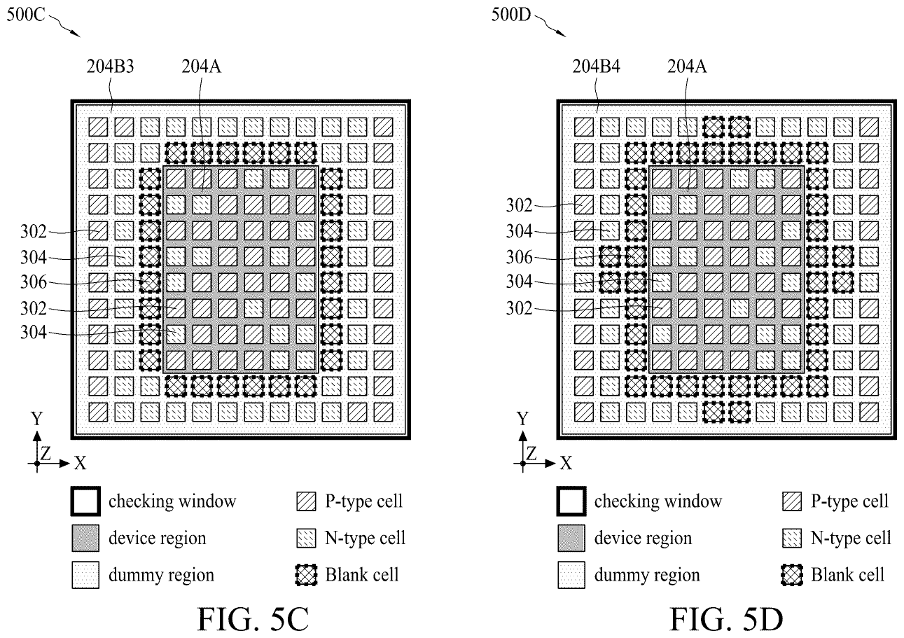

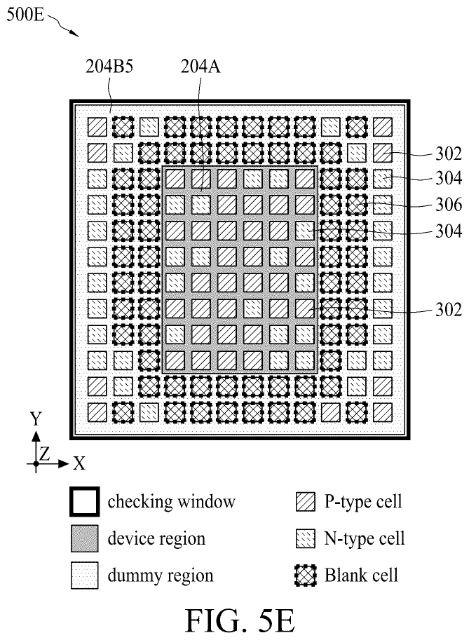

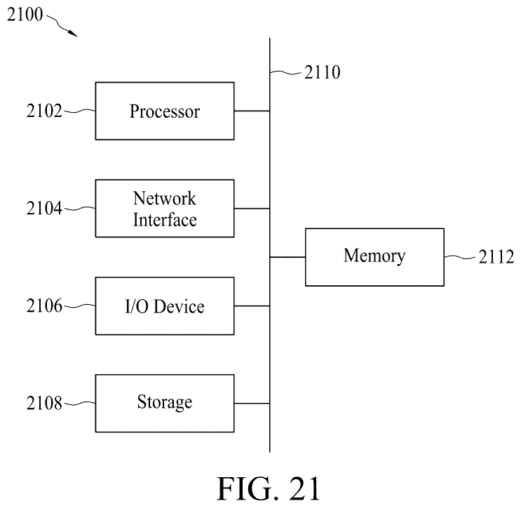

In some implementations, the selection of the numbers and configurations of the dummy P-type cells 302, the dummy N-type cells 304, and/or blank cells 306 may be performed as part of block 106 of the method 100. That is, the dummy region 204B configuration may be dynamically regulated based on the determined layout of the device region 204A. In some implementations, the distribution of dummy P-type cells 302, the dummy N-type cells 304, and/or blank cells 306 in the dummy region 204B allows for converging EPI critical dimension (CD) distribution between the devices of the semiconductor structure (e.g., chip). As discussed above, the dummy P-type cells 302 and the dummy N-type cells 304 may be defined by a corresponding masking element formed in a photolithography process during the fabrication of a semiconductor substrate corresponding to the layouts of sub-regions 204. An open ratio of the mask element providing the NEPI opening affects the NEPI CD. That is, a small open ratio for NEPI (e.g., lower number of NEPI regions) can provide for a larger NEPI CD. FIG. 3A illustrates a fragmentary layout view of a portion (e.g., a sub-region 204) of the semiconductor structure 200. The layout may be generated and stored using the method 100 of FIG. 1 and/or the system 2100 of FIG. 21. Embodiment represented by FIG. 3A illustrates one configuration of the sub-region 204. Other possible configurations of the sub-region 204 are described below with reference to FIGS. 5A-12. Generally in the present disclosure, the layout or plan views are also illustrative of a semiconductor structure corresponding to said layout as the layout will be fabricated into a semiconductor structure upon conclusion of the fabrication processes.

With reference to FIG. 3A, the device region 204A includes a number P1 of functional P-type cells 302 having p-type transistors and a number N1 of functional N-type cells 304 having n-type transistors, P1 is no less than 0, and N1 is no less than 0. As described above, depending on various design requirements of the device region 204A, the number P1 of functional P-type cells 302 of the device region 204A may be greater than, equal to, or less than the number N1 of functional N-type cells 304 of the device region 204A. In this illustrated example, the device region 204A has more functional P-type cells 302 than the functional N-type cells 304. That is, the number N1 is less than the number P1. In an embodiment, a ratio of the number N1 to the number P1 is substantially equal to 1:2. The positional arrangement of the functional P-type cells 302 and the functional N-type cells 304 of the device region 204A′ is just an example and is not intended to be limiting.

The dummy region 204B includes a number P2 of dummy P-type cells 302 having p-type transistors, a number N2 of dummy N-type cells 304 having n-type transistors, and a number M of blank cells 306, P2 is no less than 0, N2 is no less than 0, and M is no less than 0. In the present disclosure, to achieve converged EPI critical dimension (CD) distribution between the devices of the semiconductor structure (e.g., chip), a total number (i.e., N1+N2) of dummy N-type cells 304 in the dummy region 204B and functional N-type cells 304 in the device region 204A is equal to a total number (i.e., P1+P2) of dummy P-type cells in the dummy region 204B and functional P-type cells in the device region 204A. That is, the sub-region 204 includes the same number of P-type cells (including both the dummy and functional P-type cells) and N-type cells (including both the dummy and functional N-type cells). The dummy P-type cells 302 and the functional P-type cells 302 may be collectively referred to as the P-type cells 302, and the dummy N-type cells 304 and the functional N-type cells 304 may be collectively referred to as the N-type cells 304. In this illustrated example, cells (i.e., P-type cells 302, N-type cells 304, and blank cells 306) of the sub-region 204 are in a twelve by twelve (row by column) arrangement, the number N1 is 16, the number P1 is 32. That is, a ratio of the number P1 to the number N1 is equal to 2. The number N2 is 40, the number P2 is 24. That is, the ratio of the number N2 to the number P2 is less than 2. The number Mis 32. As a result, the sub-region 204 includes the same number (i.e., 56 in this example) of N-type cells and P-type cells. In the present disclosure, forming the blank cells 306 provides additional benefits. For example, forming the blank cells 306 in the dummy region 204B reduces the total numbers of NEPIs and/or PEPIs to be formed over the substrate 201 without affecting the converged EPI critical dimension (CD) distribution, thereby reducing a fabrication cost. In this illustrated embodiment, the ratio of the number M to the total number (i.e., N1+N2+P1+P2+M) of cells (e.g., 302, 304, 306) of the sub-region 204 is about 22%. In some implementations, the ratio may be adjusted. That is, the sub-region 204 may have different numbers of blank cells. By adjusting the percentage of the blank cells 306, the arrangement of dummy P-type cells 302 and dummy N-type cells 304 may be dynamically regulated such that a ratio of P-type cells 302 and N-type cells 304 can be regulated to achieve the desired device functionality and performance. In this present disclosure (including embodiments described with reference to FIGS. 3A-15), the ratio of the M to the total number (i.e., N1+N2+P1+P2+M) of cells of the sub-region 204 is less than about 45%. If the ratio is greater than 45%, although the total number of N-type cells 304 may be equal to the total number of P-type cells to achieve converged EPI critical dimension (CD) distribution and each of the CD of the NPEIs and PEPIs may be substantially the same, the NEPIs and PEPIs may take less area and the CD of those EPIs may be too large, leading to unwanted parasitic capacitance. For embodiments in which the blank cells 306 are placed immediately next to the device region 204A, as represented by FIG. 3A, the blank cells 306 may further act as a defect barrier to protect the functional cells in the device region 204A, thereby improving device performance. In this illustrated embodiment, the device region 204A has more functional P-type cells 302 than the functional N-type cells 304, and to further reduce defects in the device region 204A to improve device performance, the dummy N-type cells 304 are arranged closer to the device region 204A than the dummy P-type cells 304. That is, a distance between the dummy N-type cells 304 and the device region 204A is less than a distance between the dummy P-type cells 304 and the device region 204A. In other words, the device region 204A which includes more functional P-type cells 302 is separated from the dummy P-type cells 302 by the dummy N-type cells 304. In this illustrated embodiment, the dummy P-type cells 302 is also separated from the blank cells 306 by the dummy N-type cells 304.

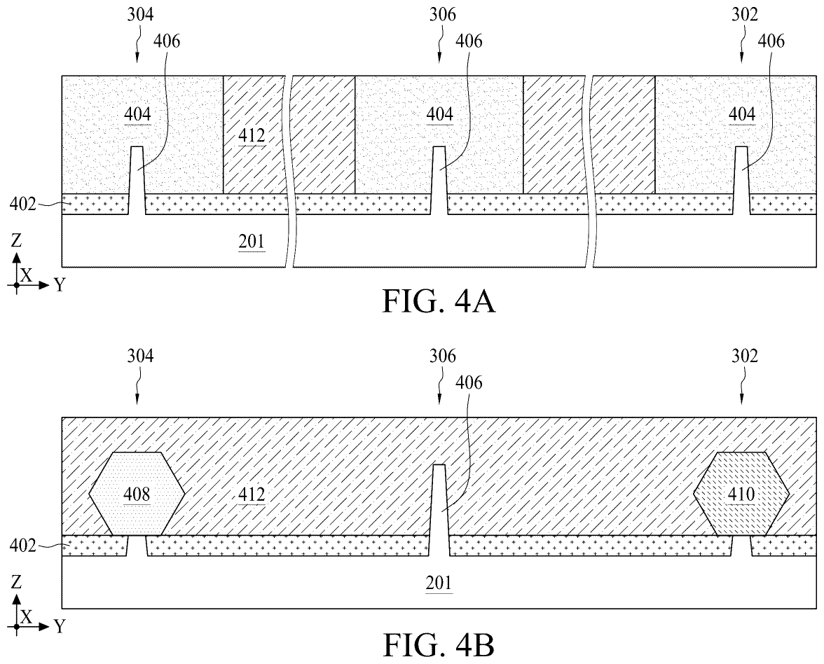

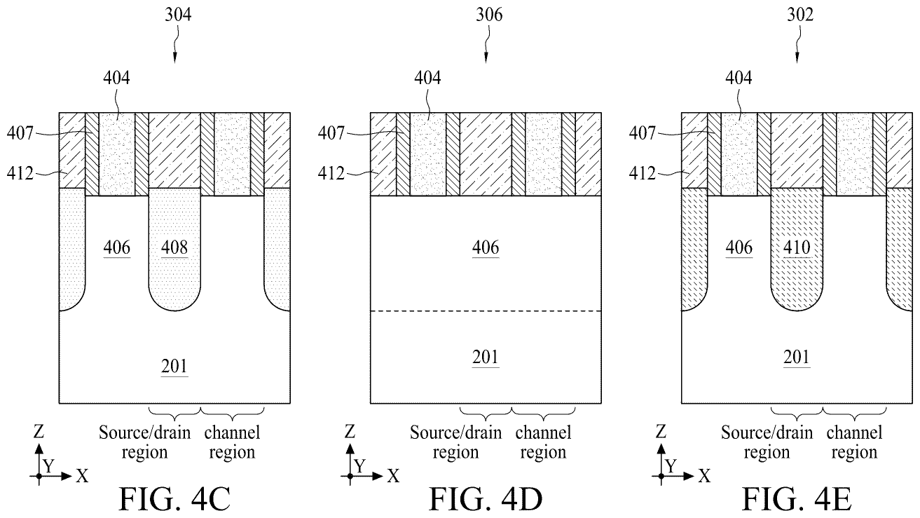

FIG. 3B depicts a fragmentary layout view of a portion of the sub-region 204 illustrating the N-type cell 304, the blank cell 306 and the P-type cell 302 shown in FIG. 3A. Each two adjacent cells of the sub-region 204 may be isolated by isolation features such as the isolation features 402 and dielectric structure 412 discussed below. FIG. 4A depicts a cross-sectional view of the portion of the sub-region 204 taken along line A-A as shown in FIG. 3B, FIG. 4B depicts a cross-sectional view of the portion of the sub-region 204 taken along line B-B as shown in FIG. 3B, FIG. 4C depicts a cross-sectional view of the portion of the sub-region 204 taken along line C-C as shown in FIG. 3B, FIG. 4D depicts a cross-sectional view of the portion of the sub-region 204 taken along line D-D as shown in FIG. 3B, FIG. 4E depicts a cross-sectional view of the portion of the sub-region 204 taken along line E-E as shown in FIG. 3B.

As shown in FIG. 3B, a number of gate structures 404 extend in a Y-direction in the top view. In some implementations, the gate structures 404 of the N-type cell 304 are substantially collinear with the gate structures 404 of the P-type cell 302 and the gate structures 404 of the blank cell 306. In an embodiment, a dielectric structure 412 (shown in FIG. 4A) interposes the gate structures 404 of the P-type cell 302 and the gate structures 404 of the blank cell 306 and interposes the gate structures 404 of the N-type cell 304 and the gate structures 404 of the blank cell 306. The gate structures 404 extend over the respective active regions 406. In some implementations as shown in FIG. 3B, the active regions 406 each extend in the X-direction in the top view.

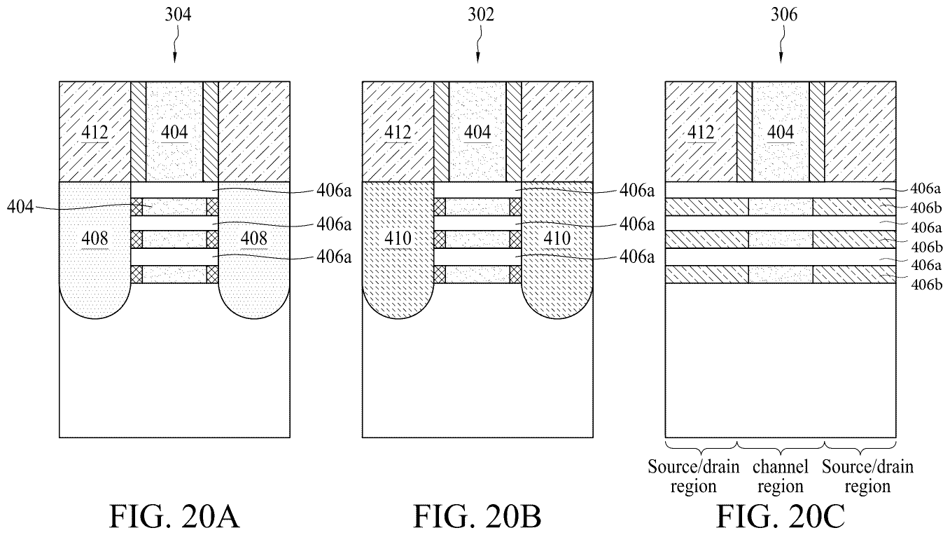

In this illustrated embodiment, the active region 406 is comprised of fin elements. Fin elements extend vertically (e.g., Z-direction) from a top surface of the substrate 201 and provide a channel region accessible from multiple sides and a top surface. In a top view, the fin elements may extend in an X-direction substantially perpendicular to the gate structures 404. In other embodiments, the active region 406 includes a planar semiconductor substrate region. In other embodiments such as the embodiment that will be described with reference to FIGS. 20A-20C, the active region 406 includes a number of nanostructures (e.g., nanowires or nanosheets) providing channel regions. In an embodiment, the active region 406 are silicon. However, other semiconductor materials including as discussed below with respect to a substrate may additionally or alternatively be implemented.

Between the active regions 406 are isolation features 402. These isolation features 402 may also be referred to as shallow trench isolation (STI) features. In some embodiments, the isolation feature 402 may include silicon oxide, silicon nitride, silicon oxynitride, fluorine-doped silicate glass (FSG), a low-k dielectric, combinations thereof, and/or other suitable materials. The isolation features 402 may include a multi-layer composition. Exemplary deposition processes include low-pressure CVD (LPCVD), CVD, plasma-enhanced CVD (PECVD), physical vapor deposition (PVD), atomic layer deposition (ALD), thermal oxidation, e-beam evaporation, or other suitable deposition techniques, or combinations thereof.

The gate structure 404 includes gate dielectric layer and gate electrode over the gate dielectric layer. In some embodiments, the gate structure 404 is a polysilicon gate providing an electrode of polysilicon, the gate dielectric layer may be silicon oxide. In some other embodiments, the gate structure 404 may be high-k metal gate structure formed using a dummy gate structure (e.g., poly gate discussed above) that is subsequently replaced through a replacement gate process. In some embodiments, the gate dielectric layer may include an interfacial layer and a high-k dielectric layer. High-K gate dielectrics, as used and described herein, include dielectric materials having a high dielectric constant, for example, greater than that of thermal silicon oxide (˜3.9). The interfacial layer may include a dielectric material such as silicon oxide, hafnium silicate, or silicon oxynitride. The interfacial layer may be deposited using chemical oxidation, thermal oxidation, ALD, CVD, and/or other suitable method. The high-K dielectric layer may include hafnium oxide, titanium oxide, hafnium zirconium oxide, tantalum oxide, hafnium silicon oxide, zirconium silicon oxide, lanthanum oxide, aluminum oxide, zirconium oxide, yttrium oxide, SrTiO₃ (STO), BaTiO₃ (BTO), BaZrO, hafnium lanthanum oxide, lanthanum silicon oxide, aluminum silicon oxide, hafnium tantalum oxide, hafnium titanium oxide, (Ba,Sr) TiO₃ (BST), silicon nitride, silicon oxynitride, combinations thereof, or other suitable material. The high-K dielectric layer may be formed by ALD, physical vapor deposition (PVD), CVD, oxidation, and/or other suitable methods. The gate electrode of the gate structure 404 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. In various embodiments, the gate electrode may be formed by ALD, PVD, CVD, e-beam evaporation, or other suitable process. The gate electrode may include an n-type work function metal layer or a p-type work function metal layer corresponding to the functionality of device. The n-type work function metal layer may include Ti, Al, Ag, Mn, Zr, TiAl, TiAlC, TaC, TaCN, TaSiN, TaAl, TaAlC, TiAlN, other n-type work function material, or combinations thereof. A p-type function metal layer such as TiN, TaN, Ru, Mo, Al, WN, ZrSi₂, MoSi₂, TaSi₂, NiSi₂, WCN, other p-type work function material, or combinations thereof. Gate spacers 407 may be formed along sidewall surfaces of the gate structures 404. In some embodiments, the gate spacers 407 may include silicon oxide, silicon oxycarbide, silicon carbonitride, silicon nitride, zirconium oxide, aluminum oxide, or a suitable dielectric material. The gate spacers 407 may be a single-layer structure or a multi-layer structure. For embodiments in which the semiconductor structure 200 includes GAA transistors, the GAA transistors also includes inner spacer features 409 disposed between the two adjacent nanostructures. The inner spacer features 409 may include silicon nitride, silicon oxycarbonitride, silicon carbonitride, silicon oxide, silicon oxycarbide, silicon carbide, or silico oxynitride.

Between gate structures 404, NEPIs 408 and PEPIs 410 are formed over source/drain regions of the active regions 406. Suitable epitaxial processes for forming the PEPIs 410 include CVD deposition techniques (e.g., vapor-phase epitaxy (VPE) and/or ultra-high vacuum CVD (UHV-CVD)), molecular beam epitaxy (MBE), and/or other suitable processes. The epitaxial growth process may use gaseous and/or liquid precursors, which interact with the composition of the active region 406. When forming the PEPIs 410 in the P-type cells 302, the source/drain regions for forming the NEPIs thereon may be masked. In various embodiments, the PEPIs 410 may include Si, Ge, AlGaAs, SiGe, boron-doped SiGe (SiGeB), or other suitable material. PEPIs 410 may be in-situ doped during the epitaxial process by introducing doping species including p-type dopants, such as boron or BF₂, and/or other suitable dopants including combinations thereof. In some implementations, an implantation process may be performed to dope the PEPIs 410. Suitable epitaxial processes for forming NEPIs 408 may be similar to the epitaxial processes for forming PEPIs 410. In various embodiments, the NEPIs 408 may include Si, GaAs, GaAsP, SiP, or other suitable material. The NEPIs 408 may be in-situ doped during the epitaxial process by introducing doping species including n-type dopants, such as phosphorus or arsenic; and/or other suitable dopants including combinations thereof. In some implementations, an implantation process may be performed to dope the NEPIs 408. Since source/drain regions of the active regions 406 of the blank cells 306 are not exposed during the formation of NEPIs 408 and PEPIs 410, source/drain features of the active regions 406 of the blank cells 306 are not recessed. As a result, the blank cells 306 do not includes NEPIs 408 or PEPIs 410. Upon fabrication of the semiconductor structure 200, the source/drain regions and channel region of blank cells 306 in the FinFET-based semiconductor structure 200 or planar MOSFET based semiconductor structure 200 have the same composition (e.g., silicon); and the source/drain regions of blank cells 306 in the GAA transistor-based semiconductor structure 200 (described with reference to FIGS. 20A-20C) include a stack of alternating first semiconductor layers (e.g., Si) and second semiconductor layers (e.g., SiGe), and each channel region of blank cells 306 in the GAA transistor-based semiconductor structure 200 include a number of nanostructures. In some implementations, a contact is formed to one or more of the gate electrode or source/drain features of transistors of the functional P-type cells 302 or functional N-type cells 304 in the device region 204A.

Dielectric structure 412 interposes the NEPIs 408 and PEPIs 410 as well as the gate structures 404. In an embodiment, the dielectric structure 412 may include a contact etch stop layer (CESL) and an interlayer dielectric (ILD) layer over the CESL. The CESL may include silicon nitride, silicon oxide, silicon oxynitride, and/or other materials known in the art and may be formed by ALD, plasma-enhanced chemical vapor deposition (PECVD) process and/or other suitable deposition or oxidation processes. In some embodiments, the ILD layer includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer may be deposited by a PECVD process or other suitable deposition technique. Since the source/drain region of the active region 406 in the blank cell 306 are not recessed, the dielectric structure 412 is also disposed over and in direct contact with the active region 406, as represented by FIG. 4B and FIG. 4D.

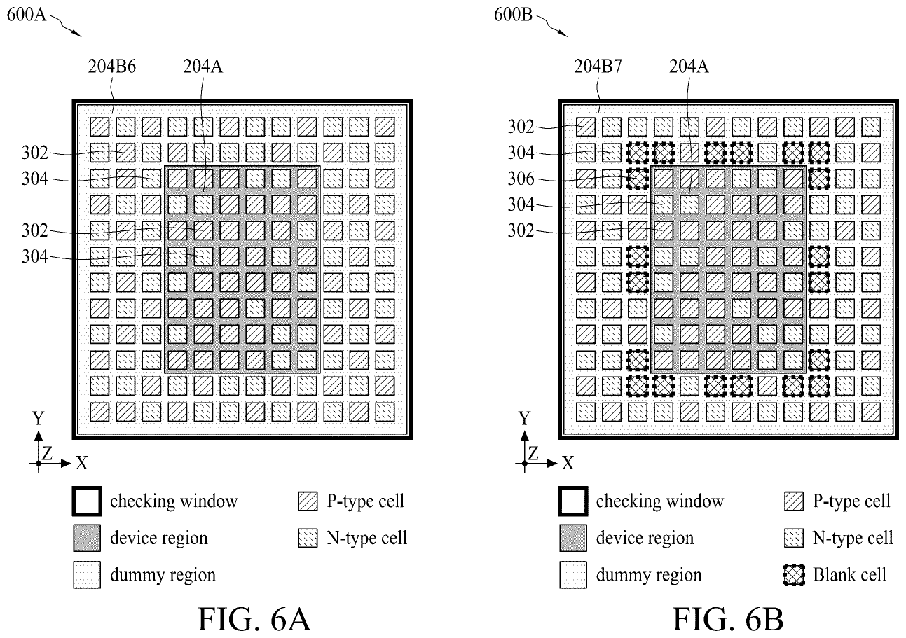

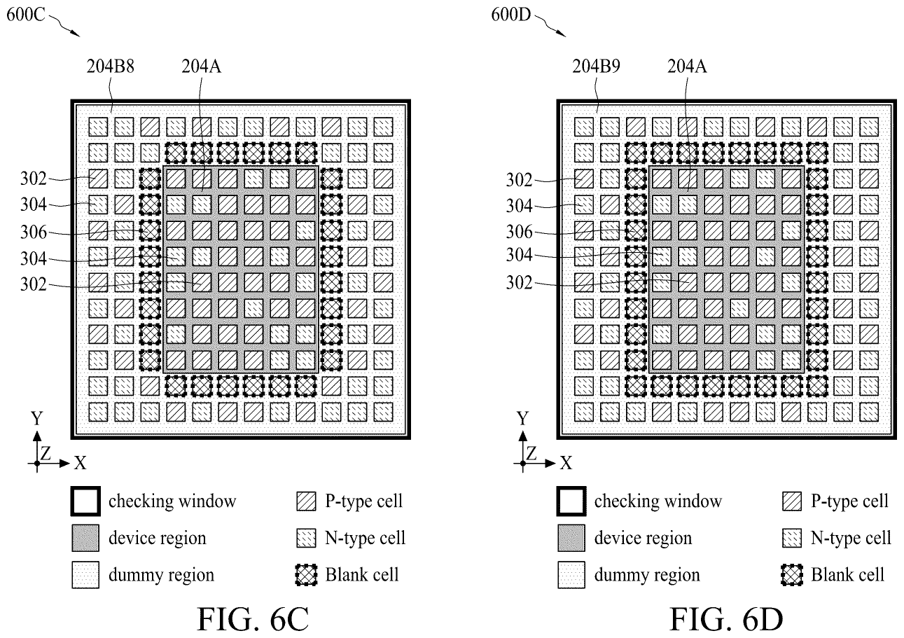

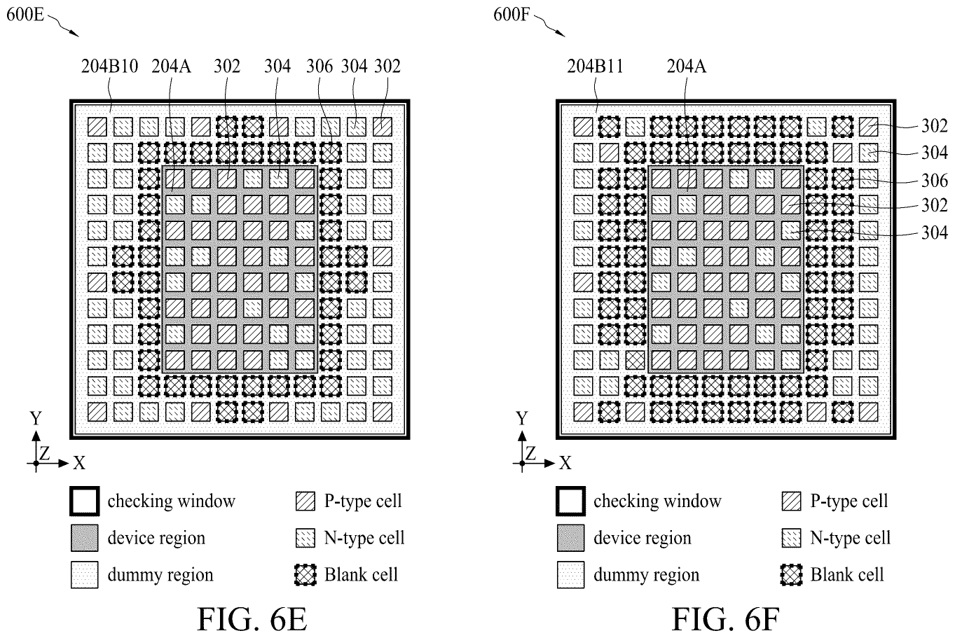

In the above embodiment described with FIG. 3A, cells (i.e., P-type cells 302, N-type cells 304, and blank cells 306) of the sub-region 204 are in a twelve by twelve (row by column) arrangement, and the number N1 of the functional N-type cells 304 is 16, the number P1 of the functional P-type cells 302 is 32, the number N2 of the dummy N-type cells 304 is 40, the number P2 of the dummy P-type cells 302 is 24, and the number M of the blank cells 306 is 32, and in the top view, the blank cells 306 surrounds the device region 204A. In other alternative embodiments, such as the embodiments represented by FIGS. 5A-5E and FIGS. 6A-6F, for the sub-regions 204 having the same device region 204A, the configuration of the dummy region 204B may be flexibly adjusted to provide similar benefits described above. The layout views and cross-sectional views of the P-type cell 302, the N-type cell 304, and the blank cells 306 in subsequent embodiments are substantially the same to those described with reference to FIGS. 3B and FIGS. 4A-4E, and repeated description is omitted for reason of simplicity.

FIGS. 5A-5E illustrate embodiments in which the sub-regions 500A-500E each have a different number M of the blank cells 306 (and thus the percentage of the blank cells 306 of the sub-region 204) than the sub-region 204, and the dummy N-type cells 304 provides isolation between the device region 204A and the dummy P-type cells 302. More specifically, FIG. 5A depicts a fragmentary top view of a sub-region 500A including the device region 204A described above and a dummy region 204B1 surrounding the device region 204A. The dummy region 204B1 is similar to the dummy region 204B described above, and two main differences between the dummy region 204B1 and the dummy region 204B include that, the dummy region 204B1 does not include blank cells 306 described above, and the number N2 of the dummy N-type cells 304 and the number P2 of the dummy P-type cells 302 are different than those of the dummy region 204B represented by FIG. 3A. For example, in this illustrated embodiment, the number N1 of the functional N-type cells 304 is 16, the number P1 of the functional P-type cells 302 is 32, the number N2 of the dummy N-type cells 304 is 56, the number P2 of the dummy P-type cells 302 is 40, and the number M of the blank cells 306 is 0. As such, a total number (i.e., N1+N2) of N-type cells is 72 is equal to a total number (i.e., P1+P2) of P-type cells is 72, and a percentage of the number M of the blank cells 306 to the total number of cells in the sub-region 500A is zero.

FIG. 5B depicts a fragmentary top view of a sub-region 500B including the device region 204A described above and a dummy region 204B2 surrounding the device region 204A. The sub-region 500B has an equal number of P-type cells 302 and N-type cells 304. The dummy region 204B2 is similar to the dummy region 204B described above, and two main differences between the dummy region 204B2 and the dummy region 204B include that, the dummy region 204B2 has a different number M of blank cells 306 and thus different numbers of dummy N-type cells 304 and dummy P-type cells 302. For example, in this illustrated embodiment, a ratio of the number M of the blank cells 306 to the total number of cells (e.g., 302, 304, 306) of the sub-region 500B is about 15%. For the sub-region 500B having the twelve by twelve (row by column) arrangement represented by FIG. 5B, the number N1 of the functional N-type cells 304 is 16, the number P1 of the functional P-type cells 302 is 32, the number N2 of the dummy N-type cells 304 is 46, the number P2 of the dummy P-type cells 302 is 30, and the number M of the blank cells 306 is 20. As such, a total number (i.e., N1+N2) of N-type cells is 62, and a total number (i.e., P1+P2) of P-type cells is 62.

FIG. 5C depicts a fragmentary top view of a sub-region 500C including the device region 204A described above and a dummy region 204B3 surrounding the device region 204A. The sub-region 500C has an equal number of P-type cells 302 and N-type cells 304. The dummy region 204B3 is similar to the dummy region 204B described above, and two main differences between the dummy region 204B3 and the dummy region 204B include that, the dummy region 204B3 has a different number M of blank cells 306 and thus different numbers of dummy N-type cells 304 and dummy P-type cells 302. For example, in this illustrated embodiment, a ratio of the number M of the blank cells 306 to the total number of cells (e.g., 302, 304, 306) of the sub-region 500C is about 20%. For the sub-region 500C having the twelve by twelve (row by column) arrangement represented by FIG. 5C, the number N1 of the functional N-type cells 304 is 16, the number P1 of the functional P-type cells 302 is 32, the number N2 of the dummy N-type cells 304 is 42, the number P2 of the dummy P-type cells 302 is 26, and the number M of the blank cells 306 is 28. As such, each of the total number (i.e., N1+N2) of N-type cells 304 and the total number (i.e., P1+P2) of P-type cells 302 is 58. Each of the dummy P-type cells 302 is separated from the device region 204A by either the dummy N-type cells 304 or the blank cells 306.

FIG. 5D depicts a fragmentary top view of a sub-region 500D including the device region 204A described above and a dummy region 204B4 surrounding the device region 204A. The sub-region 500D has an equal number of P-type cells 302 and N-type cells 304. The dummy region 204B4 is similar to the dummy region 204B described above, and two main differences between the dummy region 204B4 and the dummy region 204B include that, the dummy region 204B4 has a different number M of blank cells 306 and thus different numbers of dummy N-type cells 304 and dummy P-type cells 302. For example, in this illustrated embodiment, a ratio of the number M of the blank cells 306 to the total number of cells (e.g., 302, 304, 306) of the sub-region 500D is about 30%. For the sub-region 500D having the twelve by twelve (row by column) arrangement represented by FIG. 5D, the number N1 of the functional N-type cells 304 is 16, the number P1 of the functional P-type cells 302 is 32, the number N2 of the dummy N-type cells 304 is 36, the number P2 of the dummy P-type cells 302 is 20, and the number M of the blank cells 306 is 40. As such, each of the total number (i.e., N1+N2) of N-type cells 304 and the total number (i.e., P1+P2) of P-type cells 302 is 52.

FIG. 5E depicts a fragmentary top view of a sub-region 500E including the device region 204A described above and a dummy region 204B5 surrounding the device region 204A. The sub-region 500E has an equal number of P-type cells 302 and N-type cells 304. The dummy region 204B5 is similar to the dummy region 204B described above, and two main differences between the dummy region 204B5 and the dummy region 204B include that, the dummy region 204B5 has a different number M of blank cells 306 and thus different numbers of dummy N-type cells 304 and dummy P-type cells 302. For example, in this illustrated embodiment, a ratio of the number M of the blank cells 306 to the total number of cells (e.g., 302, 304, 306) of the sub-region 500D is about 45%. For the sub-region 500E having the twelve by twelve (row by column) arrangement represented by FIG. 5E, the number N1 of the functional N-type cells 304 is 16, the number P1 of the functional P-type cells 302 is 32, the number N2 of the dummy N-type cells 304 is 25, the number P2 of the dummy P-type cells 302 is 9, and the number M of the blank cells 306 is 62. As such, each of the total number (i.e., N1+N2) of N-type cells 304 and the total number (i.e., P1+P2) of P-type cells 302 is 41.

In the above embodiments described with reference to FIGS. 3A and 5A-5E, all the dummy N-type cells 304 are placed immediately adjacent to the device region 204A or the blank cells 306 such that the dummy P-type cells 302 are separated from the device region 204A. In some other alternative embodiments, the dummy P-type cells 302 and the dummy N-type cells 304 each may be randomly placed. For example, each of FIGS. 6A-6F illustrates a fragmentary top view of a sub-region 600A/600B/600C/600D/600E/600F including the device region 204A described above and a corresponding dummy region 204B6/204B7/204B8/204B9/204B 10/204B11 surrounding the device region 204A, respectively. The device region 204A and top and cross-sectional views of the P-type cell 302, N-type cell 304, and blank cell 306 have been described above and repeated description is omitted for reason of simplicity. The dummy P-type cells 302 and the dummy N-type cells 304 in the dummy region 204B6/204B7/204B8/204B9/204B10/204B 11 are randomly placed, and each of the dummy region 204B6/204B7/204B8/204B9/204B 10/204B11 has a different percentage of blank cells 306.

More specifically, FIG. 6A depicts a fragmentary top view of a sub-region 600A including the device region 204A described above with reference to FIG. 3A and a dummy region 204B6 surrounding the device region 204A. The sub-region 600A has an equal number of P-type cells 302 and N-type cells 304. The dummy region 204B11 is similar to the dummy region 204B described above, and main differences between the dummy region 204B6 and the dummy region 204B include that, the dummy region 204B6 has a different number M of blank cells 306 and thus different numbers of dummy N-type cells 304 and dummy P-type cells 302, and the dummy N-type cells 304 and dummy P-type cells 302 are randomly placed within the dummy region 204B of the sub-region 600A. For example, in this illustrated embodiment, the number N1 of the functional N-type cells 304 is 16, the number P1 of the functional P-type cells 302 is 32, the number N2 of the dummy N-type cells 304 is 56, the number P2 of the dummy P-type cells 302 is 40, and the number M of the blank cells 306 is 0. As such, a total number (i.e., N1+N2) of N-type cells is 72 is equal to a total number (i.e., P1+P2) of P-type cells is 72, and a percentage of the number M of the blank cells 306 to the total number of cells in the sub-region 600A is zero. Each of the dummy P-type cells 302 may be placed immediately adjacent to the device region 204A or may be placed far away from the device region 204A. Similarly, each of the dummy N-type cells 304 may be placed immediately adjacent to the device region 204A or may be placed far away from the device region 204A.

FIG. 6B depicts a fragmentary top view of a sub-region 600B including the device region 204A described above and a dummy region 204B7 surrounding the device region 204A. The sub-region 600B has an equal number of P-type cells 302 and N-type cells 304. The dummy region 204B7 is similar to the dummy region 204B6 described above, and the differences between the dummy region 204B6 and the dummy region 204B7 include that, the dummy region 204B7 has a different number M of blank cells 306 and thus different numbers of dummy N-type cells 304 and dummy P-type cells 302. For example, in this illustrated embodiment, a ratio of the number M of the blank cells 306 to the total number of cells (e.g., 302, 304, 306) of the sub-region 600B is about 15%. For the sub-region 600B having the twelve by twelve (row by column) arrangement represented by FIG. 6B, the number N1 of the functional N-type cells 304 is 16, the number P1 of the functional P-type cells 302 is 32, the number N2 of the dummy N-type cells 304 is 46, the number P2 of the dummy P-type cells 302 is 30, and the number M of the blank cells 306 is 20. As such, a total number (i.e., N1+N2) of N-type cells is 62, and a total number (i.e., P1+P2) of P-type cells is 62. Each of the blank cells 306 is disposed immediately adjacent to the device region 204A. Each of the dummy P-type cells 302 may be placed immediately adjacent to the device region 204A or the blank cells 306. Each of the dummy P-type cells 302 may also be placed far away from the device region 204A. Similarly, each of the dummy N-type cells 304 may be placed immediately adjacent to the device region 204A or the blank cells 306, or each of the dummy N-type cells 304 may be placed far away from the device region 204A.

FIG. 6C depicts a fragmentary top view of a sub-region 600C including the device region 204A described above and a dummy region 204B8 surrounding the device region 204A. The sub-region 600C has an equal number of P-type cells 302 and N-type cells 304. The dummy region 204B8 is similar to the dummy region 204B6 described above, and main differences between the dummy region 204B8 and the dummy region 204B include that, the dummy region 204B8 has a different number M of blank cells 306 and thus different numbers of dummy N-type cells 304 and dummy P-type cells 302. For example, in this illustrated embodiment, a ratio of the number M of the blank cells 306 to the total number of cells (e.g., 302, 304, 306) of the sub-region 600C is about 20%. For the sub-region 600C having the twelve by twelve (row by column) arrangement represented by FIG. 6C, the number N1 of the functional N-type cells 304 is 16, the number P1 of the functional P-type cells 302 is 32, the number N2 of the dummy N-type cells 304 is 42, the number P2 of the dummy P-type cells 302 is 26, and the number M of the blank cells 306 is 28. As such, each of the total number (i.e., N1+N2) of N-type cells 304 and the total number (i.e., P1+P2) of P-type cells 302 is 58. The blank cells 306 are placed immediately adjacent the device region 204A. Each of the dummy P-type cells 302 may be separated from the blank cells 306 by the dummy N-type cells 304 or may be placed immediately adjacent to the blank cells 306. Similarly, each of the dummy N-type cells 304 may be separated from the blank cells 306 by the dummy P-type cells 302 or may be placed immediately adjacent to the blank cells 306.

FIG. 6D depicts a fragmentary top view of a sub-region 600D including the device region 204A described above and a dummy region 204B9 surrounding the device region 204A. The sub-region 600D has an equal number of P-type cells 302 and N-type cells 304. The dummy region 204B9 is similar to the dummy region 204B6 described above, and main differences between the dummy region 204B9 and the dummy region 204B include that, the dummy region 204B9 has a different number M of blank cells 306 and thus different numbers of dummy N-type cells 304 and dummy P-type cells 302. For example, in this illustrated embodiment, a ratio of the number M of the blank cells 306 to the total number of cells (e.g., 302, 304, 306) of the sub-region 600D is about 22%. For the sub-region 600D having the twelve by twelve (row by column) arrangement represented by FIG. 6D, the number N1 of the functional N-type cells 304 is 16, the number P1 of the functional P-type cells 302 is 32, the number N2 of the dummy N-type cells 304 is 40, the number P2 of the dummy P-type cells 302 is 24, and the number M of the blank cells 306 is 32. As such, each of the total number (i.e., N1+N2) of N-type cells 304 and the total number (i.e., P1+P2) of P-type cells 302 is 56. The blank cells 306 are placed immediately adjacent the device region 204A. Each of the dummy P-type cells 302 may be separated from the blank cells 306 by the dummy N-type cells 304 or may be placed immediately adjacent to the blank cells 306. Similarly, each of the dummy N-type cells 304 may be separated from the blank cells 306 by the dummy P-type cells 302 or may be placed immediately adjacent to the blank cells 306.

FIG. 6E depicts a fragmentary top view of a sub-region 600E including the device region 204A described above and a dummy region 204B10 surrounding the device region 204A. The sub-region 600E has an equal number of P-type cells 302 and N-type cells 304. The dummy region 204B10 is similar to the dummy region 204B6 described above, and main differences between the dummy region 204B10 and the dummy region 204B include that, the dummy region 204B 10 has a different number M of blank cells 306 and thus different numbers of dummy N-type cells 304 and dummy P-type cells 302. For example, in this illustrated embodiment, a ratio of the number M of the blank cells 306 to the total number of cells (e.g., 302, 304, 306) of the sub-region 600E is about 30%. For the sub-region 600E having the twelve by twelve (row by column) arrangement represented by FIG. 6E, the number N1 of the functional N-type cells 304 is 16, the number P1 of the functional P-type cells 302 is 32, the number N2 of the dummy N-type cells 304 is 36, the number P2 of the dummy P-type cells 302 is 20, and the number M of the blank cells 306 is 40. As such, each of the total number (i.e., N1+N2) of N-type cells 304 and the total number (i.e., P1+P2) of P-type cells 302 is 52. The blank cells 306 are placed immediately adjacent the device region 204A. Each of the dummy P-type cells 302 may be separated from the blank cells 306 by the dummy N-type cells 304 or may be placed immediately adjacent to the blank cells 306. Similarly, each of the dummy N-type cells 304 may be separated from the blank cells 306 by the dummy P-type cells 302 or may be placed immediately adjacent to the blank cells 306.

FIG. 6F depicts a fragmentary top view of a sub-region 600F including the device region 204A described above and a dummy region 204B11 surrounding the device region 204A. The sub-region 600F has an equal number of P-type cells 302 and N-type cells 304. The dummy region 204B11 is similar to the dummy region 204B6 described above, and main differences between the dummy region 204B11 and the dummy region 204B include that, the dummy region 204B11 has a different number M of blank cells 306 and thus different numbers of dummy N-type cells 304 and dummy P-type cells 302. For example, in this illustrated embodiment, a ratio of the number M of the blank cells 306 to the total number of cells (e.g., 302, 304, 306) of the sub-region 600F is about 45%. For the sub-region 600F having the twelve by twelve (row by column) arrangement represented by FIG. 6F, the number N1 of the functional N-type cells 304 is 16, the number P1 of the functional P-type cells 302 is 32, the number N2 of the dummy N-type cells 304 is 25, the number P2 of the dummy P-type cells 302 is 9, and the number M of the blank cells 306 is 62. As such, each of the total number (i.e., N1+N2) of N-type cells 304 and the total number (i.e., P1+P2) of P-type cells 302 is 41. The blank cells 306 are placed immediately adjacent the device region 204A. Each of the dummy P-type cells 302 may be separated from the blank cells 306 by the dummy N-type cells 304 or may be placed immediately adjacent to the blank cells 306. Similarly, each of the dummy N-type cells 304 may be separated from the blank cells 306 by the dummy P-type cells 302 or may be placed immediately adjacent to the blank cells 306.

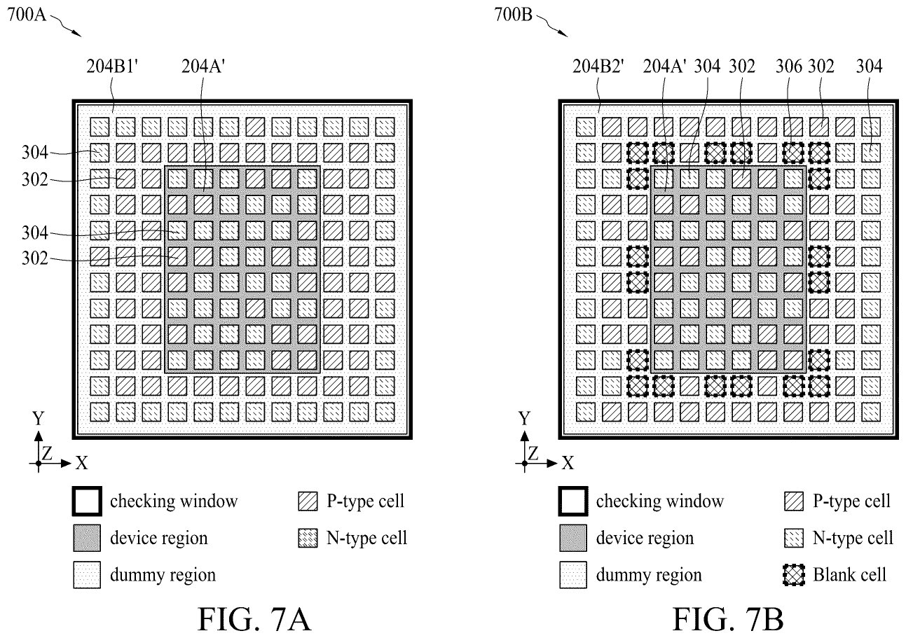

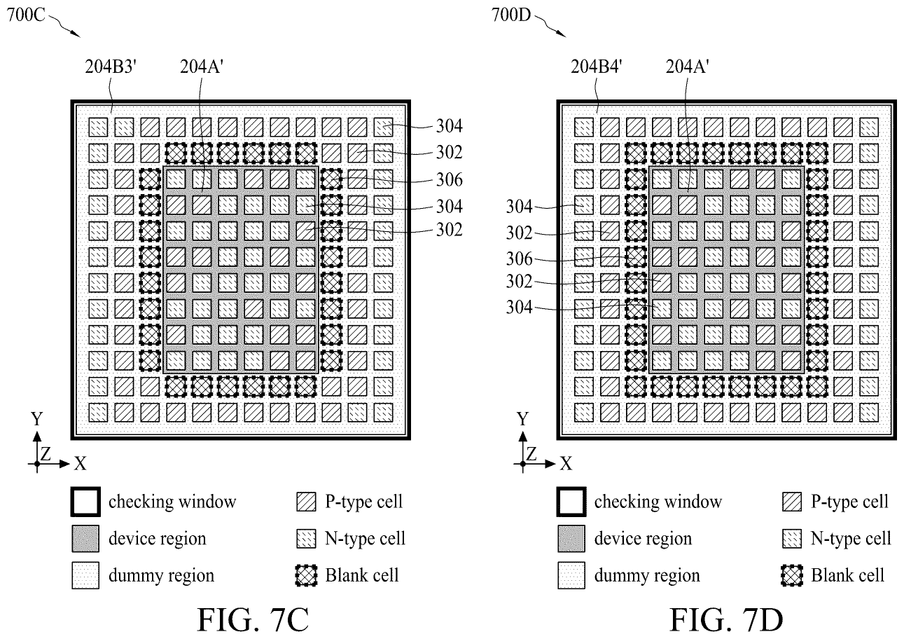

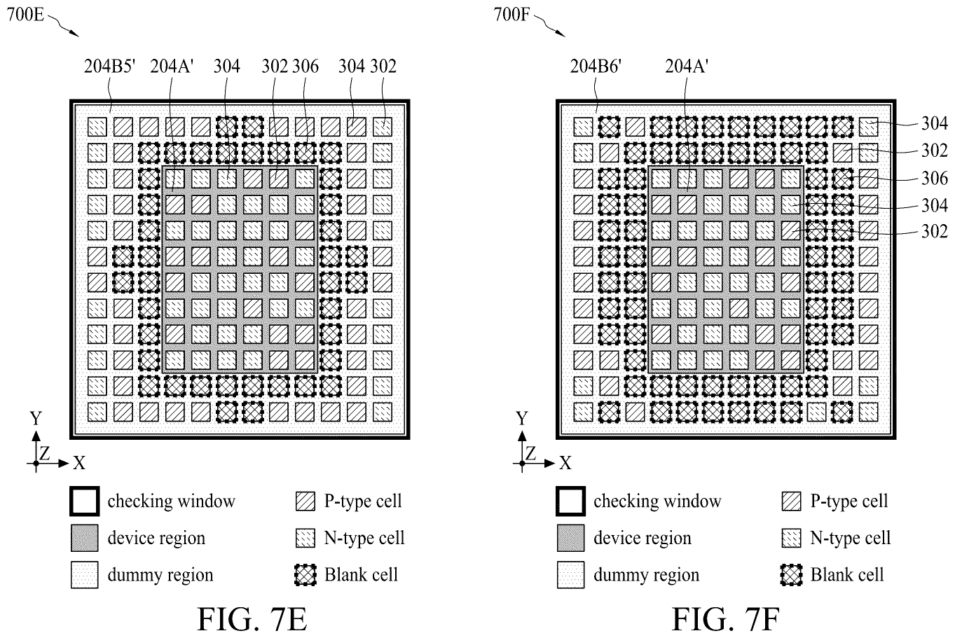

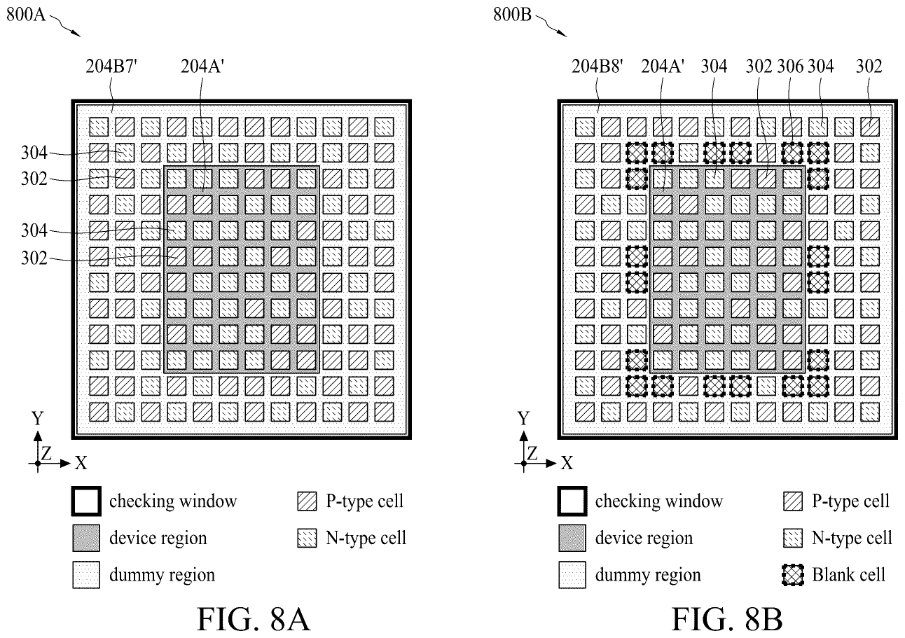

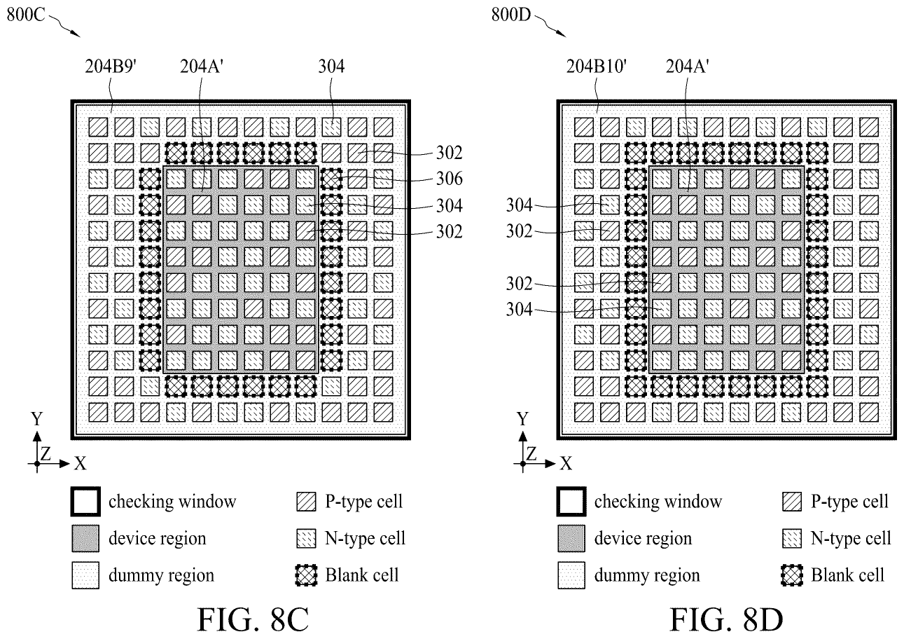

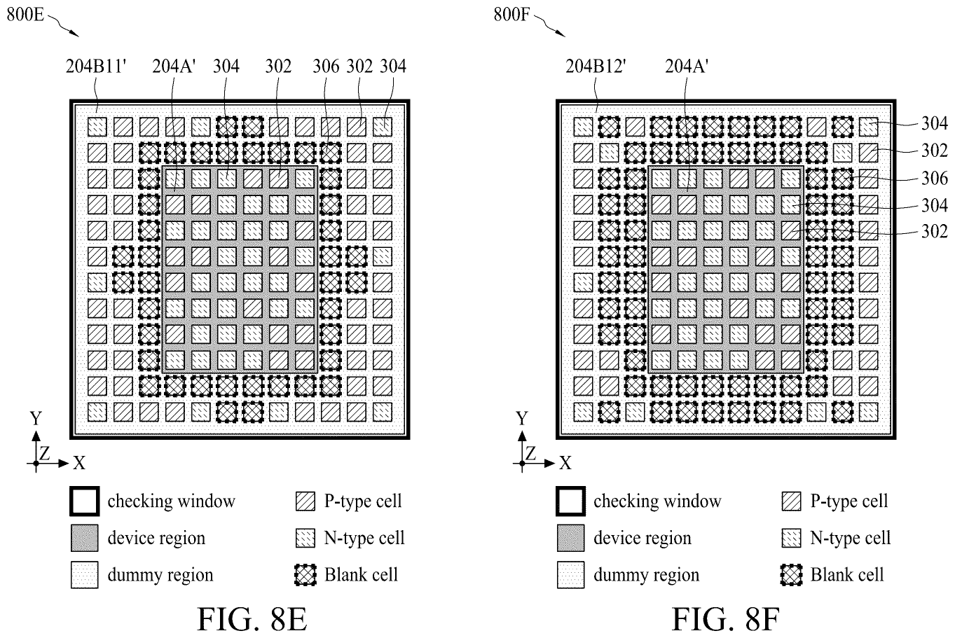

In the above embodiments described with reference to FIG. 3A, FIGS. 5A-5E and FIGS. 6A-6F, the device region 204A has the number P1 of functional P-type cells 302 and the number N1 of functional N-type cells 304, and N1 is less than P1. In some other embodiments, the number N1 of functional N-type cells 304 is greater than the number P1 of the functional P-type cells 302, and the number N2 of dummy N-type cells 304 is less than the number P2 of the dummy P-type cells 302 such that the total number (i.e., N1+N2) of N-type cells 304 is equal to the total number (i.e., P1+P2) of P-type cells 304. FIGS. 7A-7F and FIGS. 8A-8F depict such examples. More specifically, for embodiments represented by each of the figures FIGS. 7A-7F, the sub-region includes a device region 204A′ having more functional N-type cells 304 than functional P-type cells 302, and the dummy P-type cells 302 are disposed either immediately adjacent to the device region 204A′ or immediately adjacent to the blank cells 306. For embodiments represented by each of the figures FIGS. 8A-8F, the sub-region includes the device region 204A′ having more functional N-type cells 304 than functional P-type cells 302, and the dummy P-type cells 302 and dummy N-type cells 304 may be randomly disposed within the dummy region.

FIG. 7A illustrates a fragmentary top view of a sub-region 700A including the device region 204A′ and a dummy region 204B1′ surrounding the device region 204A′. The sub-region 700A has an equal number of P-type cells 302 and N-type cells 304. In an embodiment, in the device region 204A′, a ratio of the number N1 of functional N-type cells 304 to the number P1 of functional P-type cells 302 is about 2:1. The positional arrangement of the functional P-type cells 302 and the functional N-type cells 304 of the device region 204A′ is just an example and is not intended to be limiting. The dummy region 204B1′ includes the dummy N-type cells 304 and the dummy P-type cells 302 and does not include the blank cells 306. The ratio of the number P2 of dummy P-type cells 302 to the number N2 of the dummy N-type cells 304 is less than 2, and the dummy P-type cells 302 are placed immediately adjacent to the device region 204A′ to reduce device defects, and the dummy N-type cells 304 are separated from the device region 204A′ by the dummy P-type cells 302. In this illustrated example, cells (i.e., P-type cells 302, N-type cells 304, and blank cells 306) of the sub-region 700A are in a twelve by twelve (row by column) arrangement, the number N1 is 32, the number P1 is 16. The number N2 is 40, the number P2 is 56. As such, each of the total number (i.e., N1+N2) of N-type cells 304 and the total number (i.e., P1+P2) of P-type cells 302 is 72.

FIG. 7B depicts a fragmentary top view of a sub-region 700B including the device region 204A′ described above and a dummy region 204B2′ surrounding the device region 204A′. The sub-region 700B has an equal number of P-type cells 302 and N-type cells 304. The dummy region 204B2′ is similar to the dummy region 204B1′ described above, and the differences between the dummy region 204B2′ and the dummy region 204B1′ include that, the dummy region 204B2′ has a different number M of blank cells 306 and thus different numbers of dummy N-type cells 304 and dummy P-type cells 302. For example, in this illustrated embodiment, a ratio of the number M of the blank cells 306 to the total number of cells (e.g., 302, 304, 306) of the sub-region 700B is about 15%. For the sub-region 700B having the twelve by twelve (row by column) arrangement represented by FIG. 7B, the number P1 of the functional P-type cells 302 is 16, the number N1 of the functional N-type cells 304 is 32, the number P2 of the dummy P-type cells 302 is 46, the number N2 of the dummy N-type cells 304 is 30, and the number M of the blank cells 306 is 20. As such, a total number (i.e., N1+N2) of N-type cells is 62, and a total number (i.e., P1+P2) of P-type cells is 62. Each of the blank cells 306 is disposed immediately adjacent to the device region 204A′. Each of the dummy P-type cells 302 is placed either immediately adjacent to the device region 204A′ or immediately adjacent the blank cells 306. The dummy N-type cells 304 is spaced apart from the device region 204A′ by either the blank cells 306 or the dummy P-type cells 302.

FIG. 7C depicts a fragmentary top view of a sub-region 700C including the device region 204A′ described above and a dummy region 204B3′ surrounding the device region 204A′. The sub-region 700C has an equal number of P-type cells 302 and N-type cells 304. The dummy region 204B3′ is similar to the dummy region 204B1′ described above, and differences between the dummy region 204B3′ and the dummy region 204B1′ include that, the dummy region 204B3′ has a different number M of blank cells 306 and thus different numbers of dummy N-type cells 304 and dummy P-type cells 302. For example, in this illustrated embodiment, a ratio of the number M of the blank cells 306 to the total number of cells (e.g., 302, 304, 306) of the sub-region 700C is about 20%. For the sub-region 700C having the twelve by twelve (row by column) arrangement represented by FIG. 7C, the number N1 of the functional N-type cells 304 is 32, the number P1 of the functional P-type cells 302 is 16, the number N2 of the dummy N-type cells 304 is 26, the number P2 of the dummy P-type cells 302 is 42, and the number M of the blank cells 306 is 28. As such, each of the total number (i.e., N1+N2) of N-type cells 304 and the total number (i.e., P1+P2) of P-type cells 302 is 58. Each of the blank cells 306 is disposed immediately adjacent to the device region 204A′. Each of the dummy N-type cells 304 is separated from the device region 204A′ by the dummy P-type cells 302 and the blank cells 306.

FIG. 7D depicts a fragmentary top view of a sub-region 700D including the device region 204A′ described above and a dummy region 204B4′ surrounding the device region 204A′. The sub-region 700D has an equal number of P-type cells 302 and N-type cells 304. The dummy region 204B4′ is similar to the dummy region 204B1′ described above, and differences between the dummy region 204B4′ and the dummy region 204B1′ include that, the dummy region 204B4′ has a different number M of blank cells 306 and thus different numbers of dummy N-type cells 304 and dummy P-type cells 302. For example, in this illustrated embodiment, a ratio of the number M of the blank cells 306 to the total number of cells (e.g., 302, 304, 306) of the sub-region 700D is about 22%. For the sub-region 700D having the twelve by twelve (row by column) arrangement represented by FIG. 7D, the number N1 of the functional N-type cells 304 is 32, the number P1 of the functional P-type cells 302 is 16, the number N2 of the dummy N-type cells 304 is 24, the number P2 of the dummy P-type cells 302 is 40, and the number M of the blank cells 306 is 32. As such, each of the total number (i.e., N1+N2) of N-type cells 304 and the total number (i.e., P1+P2) of P-type cells 302 is 56. Each of the blank cells 306 is disposed immediately adjacent to the device region 204A′. Each of the dummy N-type cells 304 is separated from the device region 204A′ by the dummy P-type cells 302 and the blank cells 306.

FIG. 7E depicts a fragmentary top view of a sub-region 700E including the device region 204A′ described above and a dummy region 204B5′ surrounding the device region 204A′. The sub-region 700E has an equal number of P-type cells 302 and N-type cells 304. The dummy region 204B5′ is similar to the dummy region 204B1′ described above, and differences between the dummy region 204B5′ and the dummy region 204B1′ include that, the dummy region 204B5′ has a different number M of blank cells 306 and thus different numbers of dummy N-type cells 304 and dummy P-type cells 302. For example, in this illustrated embodiment, a ratio of the number M of the blank cells 306 to the total number of cells (e.g., 302, 304, 306) of the sub-region 500D is about 30%. For the sub-region 700E having the twelve by twelve (row by column) arrangement represented by FIG. 7E, the number N1 of the functional N-type cells 304 is 32, the number P1 of the functional P-type cells 302 is 16, the number N2 of the dummy N-type cells 304 is 20, the number P2 of the dummy P-type cells 302 is 36, and the number M of the blank cells 306 is 40. As such, each of the total number (i.e., N1+N2) of N-type cells 304 and the total number (i.e., P1+P2) of P-type cells 302 is 52. The blank cells 306 are disposed immediately adjacent to the device region 204A′. Each of the dummy N-type cells 304 is separated from the device region 204A′ by the dummy P-type cells 302 and the blank cells 306.

FIG. 7F depicts a fragmentary top view of a sub-region 700F including the device region 204A′ described above and a dummy region 204B6′ surrounding the device region 204A′. The sub-region 700F has an equal number of P-type cells 302 and N-type cells 304. The dummy region 204B6′ is similar to the dummy region 204B1′ described above, and differences between the dummy region 204B6′ and the dummy region 204B1′ include that, the dummy region 204B6′ has a different number M of blank cells 306 and thus different numbers of dummy N-type cells 304 and dummy P-type cells 302. For example, in this illustrated embodiment, a ratio of the number M of the blank cells 306 to the total number of cells (e.g., 302, 304, 306) of the sub-region 500D is about 45%. For the sub-region 700F having the twelve by twelve (row by column) arrangement represented by FIG. 7F, the number N1 of the functional N-type cells 304 is 32, the number P1 of the functional P-type cells 302 is 16, the number N2 of the dummy N-type cells 304 is 9, the number P2 of the dummy P-type cells 302 is 25, and the number M of the blank cells 306 is 62. As such, each of the total number (i.e., N1+N2) of N-type cells 304 and the total number (i.e., P1+P2) of P-type cells 302 is 41. The blank cells 306 are disposed immediately adjacent to the device region 204A′. Each of the dummy N-type cells 304 is separated from the device region 204A′ by the dummy P-type cells 302 and the blank cells 306.

In the above embodiments described with reference to FIGS. 7A-7F, all the dummy P-type cells 302 are placed immediately adjacent to either the device region 204A or the blank cells 306 such that the dummy N-type cells 304 are separated from the device region 204A. In some other alternative embodiments, the dummy P-type cells 302 and the dummy N-type cells 304 each may be randomly placed. For example, each of FIGS. 8A-8F illustrates a fragmentary top view of a sub-region 800A/800B/800C/800D/800E/800F including the device region 204A′ described above and a corresponding dummy region 204B7′/204B8′/204B9′/204B10′/204B11′/204B12′ surrounding the device region 204A′, respectively. The device region 204A′ and top and cross-sectional views of the P-type cell 302, N-type cell 304, and blank cell 306 have been described above and repeated description is omitted for reason of simplicity. The dummy P-type cells 302 and the dummy N-type cells 304 in the dummy region 204B7′/204B8′/204B9′/204B10′/204B11′/204B12′ are randomly placed, and each of the dummy region 204B7′/204B8′/204B9′/204B10′/204B11′/204B12′ has a different percentage of blank cells 306.

More specifically, FIG. 8A depicts a fragmentary top view of a sub-region 800A including the device region 204A′ described above and a dummy region 204B7′ surrounding the device region 204A′. FIG. 8B depicts a fragmentary top view of a sub-region 800B including the device region 204A′ described above and a dummy region 204B8′ surrounding the device region 204A′. FIG. 8C depicts a fragmentary top view of a sub-region 800C including the device region 204A′ described above and a dummy region 204B9′ surrounding the device region 204A′. FIG. 8D depicts a fragmentary top view of a sub-region 800D including the device region 204A′ described above and a dummy region 204B9′ surrounding the device region 204A′. FIG. 8E depicts a fragmentary top view of a sub-region 800E including the device region 204A′ described above and a dummy region 204B10′ surrounding the device region 204A′. FIG. 8F depicts a fragmentary top view of a sub-region 800F including the device region 204A′ described above and a dummy region 204B11′ surrounding the device region 204A′.

Each of the sub-regions 800A, 800B, 800C, 800D, 800E, 800F has a corresponding equal number of P-type cells 302 and N-type cells 304. The dummy region 204B7′/204B8′/204B9′/204B10′/204B11′/204B12′ is similar to the dummy region 204B1′ described above, and main differences between the dummy region dummy region 204B7′/204B8′/204B9′/204B10′/204B11′/204B12′ and the dummy region 204B1′ include that, the dummy region 204B7′/204B8′/204B9′/204B10′/204B11′/204B12′ has a different number M of blank cells 306 and thus different numbers of dummy N-type cells 304 and dummy P-type cells 302, and the dummy N-type cells 304 and dummy P-type cells 302 are randomly placed within the dummy region 204B of the corresponding sub-region 800A, 800B, 800C, 800D, 800E, 800F. For example, in the illustrated embodiments, a ratio of the number M of the blank cells 306 to the total number of cells (e.g., 302, 304, 306) of the sub-region 800A is 0; a ratio of the number M of the blank cells 306 to the total number of cells (e.g., 302, 304, 306) of the sub-region 800B is about 15%; a ratio of the number M of the blank cells 306 to the total number of cells (e.g., 302, 304, 306) of the sub-region 800C is about 20%; a ratio of the number M of the blank cells 306 to the total number of cells (e.g., 302, 304, 306) of the sub-region 800D is about 22%; a ratio of the number M of the blank cells 306 to the total number of cells (e.g., 302, 304, 306) of the sub-region 800E is about 30%; and a ratio of the number M of the blank cells 306 to the total number of cells (e.g., 302, 304, 306) of the sub-region 800F is about 45%. Each of the dummy P-type cells 302 in the sub-region 800A/800B/800C/800D/800E/800F may be placed immediately adjacent to the device region 204A′ or may be placed far away from the device region 204A′. Similarly, each of the dummy N-type cells 304 may be placed immediately adjacent to the device region 204A′ or may be placed far away from the device region 204A′.

In the illustrated embodiments, for the sub-regions 800A, 800B, 800C, 800D, 800E, 800F having the twelve by twelve (row by column) arrangement represented by FIGS. 8A-8F, the number N1 of the functional N-type cells 304 is 32, the number P1 of the functional P-type cells 302 is 16. Within the sub-region 800A, the number N2 of the dummy N-type cells 304 in the sub-region 800A is 40, the number P2 of the dummy P-type cells 302 in the sub-region 800A is 56, and the number M of the blank cells 306 is 0. Within the sub-region 800B, the number N2 of the dummy N-type cells 304 in the sub-region 800B is 30, the number P2 of the dummy P-type cells 302 in the sub-region 800B is 46, and the number M of the blank cells 306 is 20. Within the sub-region 800C, the number N2 of the dummy N-type cells 304 in the sub-region 800C is 26, the number P2 of the dummy P-type cells 302 in the sub-region 800C is 42, and the number M of the blank cells 306 is 28. Within the sub-region 800D, the number N2 of the dummy N-type cells 304 in the sub-region 800D is 24, the number P2 of the dummy P-type cells 302 in the sub-region 800D is 40, and the number M of the blank cells 306 is 32. Within the sub-region 800E, the number N2 of the dummy N-type cells 304 in the sub-region 800E is 20, the number P2 of the dummy P-type cells 302 in the sub-region 800E is 36, and the number M of the blank cells 306 is 40. Within the sub-region 800F, the number N2 of the dummy N-type cells 304 in the sub-region 800E is 9, the number P2 of the dummy P-type cells 302 in the sub-region 800E is 25, and the number M of the blank cells 306 is 62.

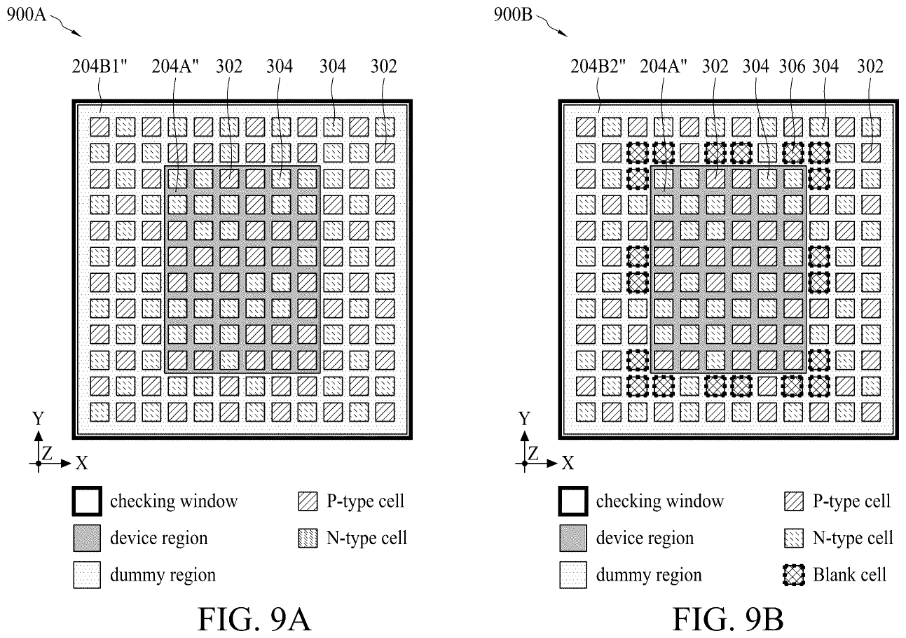

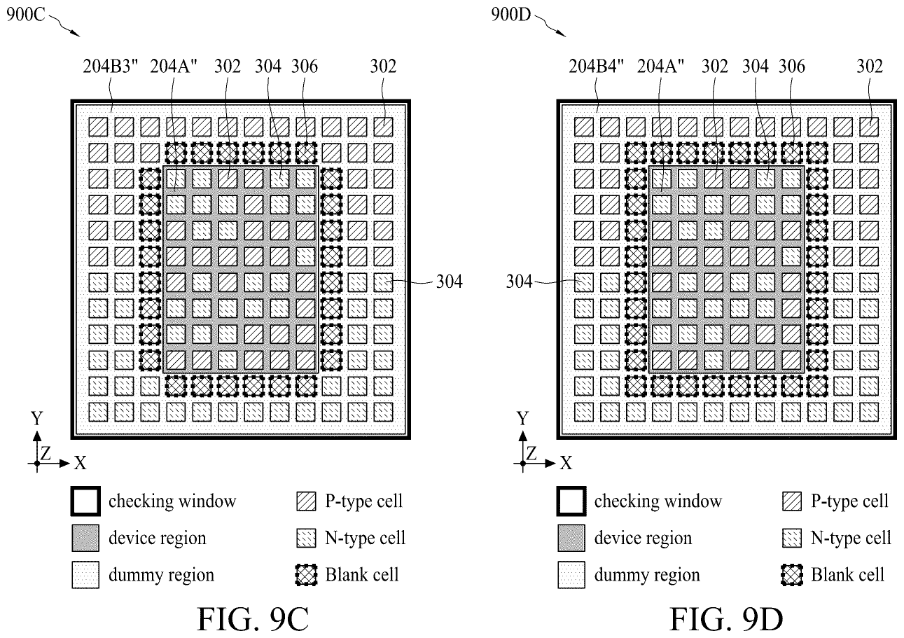

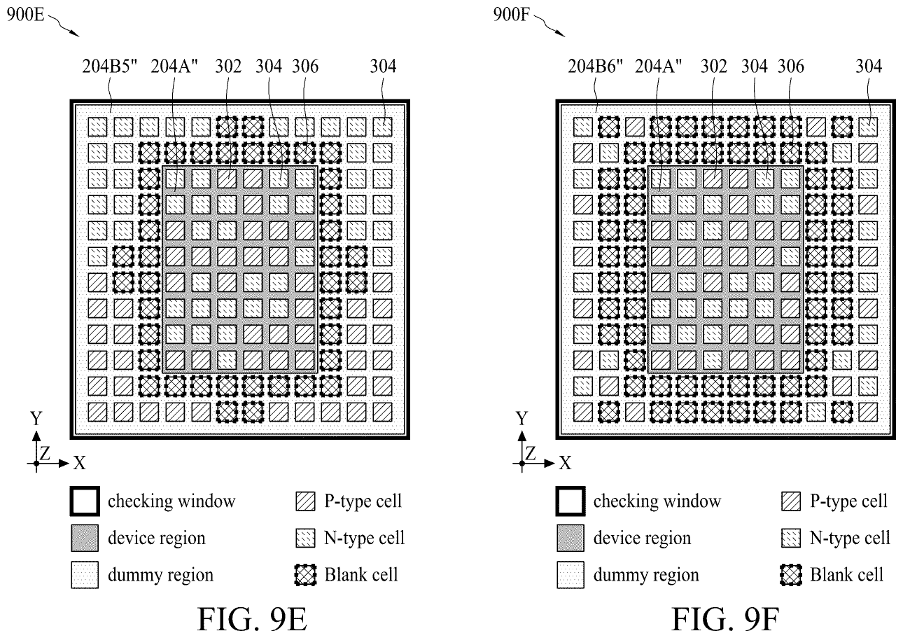

In the above embodiments described with reference to FIGS. 3A-6F, the number N1 is less than the number P1, and in the above embodiments described with reference to FIGS. 7A-8F, the number N1 is greater than the number P1. In some other embodiments, the number N1 of functional N-type cells 304 is equal to the number P1 of the functional P-type cells 302, and the number N2 of dummy N-type cells 304 is equal to the number P2 of the dummy P-type cells 302 such that the total number (i.e., N1+N2) of N-type cells 304 is equal to the total number (i.e., P1+P2) of P-type cells 304. FIGS. 9A-9F depict such examples. For embodiments represented by each of the figures FIGS. 9A-9F, each sub-region 900A/900B/900C/900D/900E/900F includes a device region 204A″ having an equal number of functional N-type cells 304 and functional P-type cells 302 and a corresponding dummy region 204B1″/204B2″/204B3″/204B4″/204B5″/204B6″ surrounding the device region 204A″ and having a respective equal number of dummy N-type cells 304 and dummy P-type cells 302 with different percentages of blank cells 306. The dummy P-type cells 302 and dummy N-type cells 304 may be randomly disposed within the corresponding dummy region. That is, each one of the dummy P-type cells 302 and the dummy N-type cells 304 can be disposed either immediately adjacent to the device region 204A″ or immediately adjacent to the blank cells 306. Top and cross-sectional views of the P-type cell 302, N-type cell 304, and blank cell 306 have been described above and repeated description is omitted for reason of simplicity.

Each of the sub-regions 900A, 900B, 900C, 900D, 900E, 900F has a corresponding equal number of P-type cells 302 and N-type cells 304. The dummy region 204B1″/204B2″/204B3″/204B4″/204B5″/204B6″ each has a different number M of blank cells 306 and thus different numbers of dummy N-type cells 304 and dummy P-type cells 302. For example, in the illustrated embodiments, a ratio of the number M of the blank cells 306 to the total number of cells (e.g., 302, 304, 306) of the sub-region 900A is 0; a ratio of the number M of the blank cells 306 to the total number of cells (e.g., 302, 304, 306) of the sub-region 900B is about 15%; a ratio of the number M of the blank cells 306 to the total number of cells (e.g., 302, 304, 306) of the sub-region 900C is about 20%; a ratio of the number M of the blank cells 306 to the total number of cells (e.g., 302, 304, 306) of the sub-region 900D is about 22%; a ratio of the number M of the blank cells 306 to the total number of cells (e.g., 302, 304, 306) of the sub-region 900E is about 30%; and a ratio of the number M of the blank cells 306 to the total number of cells (e.g., 302, 304, 306) of the sub-region 900F is about 45%. Each of the dummy P-type cells 302 in the sub-region 900A/900B/900C/900D/900E/900F may be placed immediately adjacent to the device region 204A″ or may be placed far away from the device region 204A″. Similarly, each of the dummy N-type cells 304 may be placed immediately adjacent to the device region 204A′ or may be placed far away from the device region 204A″.

In the illustrated embodiments, for the sub-regions 900A, 900B, 900C, 900D, 900E, 900F having the twelve by twelve (row by column) arrangement represented by FIGS. 9A-9F, the number N1 of the functional N-type cells 304 is 24, the number P1 of the functional P-type cells 302 is 24. Within the sub-region 900A, the number N2 of the dummy N-type cells 304 in the sub-region 800A is 48, the number P2 of the dummy P-type cells 302 in the sub-region 800A is 48, and the number M of the blank cells 306 is 0. Within the sub-region 900B, the number N2 of the dummy N-type cells 304 in the sub-region 800B is 38, the number P2 of the dummy P-type cells 302 in the sub-region 800B is 38, and the number M of the blank cells 306 is 20. Within the sub-region 900C, the number N2 of the dummy N-type cells 304 in the sub-region 800C is 34, the number P2 of the dummy P-type cells 302 in the sub-region 800C is 34, and the number M of the blank cells 306 is 28. Within the sub-region 900D, the number N2 of the dummy N-type cells 304 in the sub-region 800D is 32, the number P2 of the dummy P-type cells 302 in the sub-region 800D is 32, and the number M of the blank cells 306 is 32. Within the sub-region 900E, the number N2 of the dummy N-type cells 304 in the sub-region 900E is 28, the number P2 of the dummy P-type cells 302 in the sub-region 800E is 28, and the number M of the blank cells 306 is 40. Within the sub-region 900F, the number N2 of the dummy N-type cells 304 in the sub-region 800E is 17, the number P2 of the dummy P-type cells 302 in the sub-region 800E is 17, and the number M of the blank cells 306 is 62.

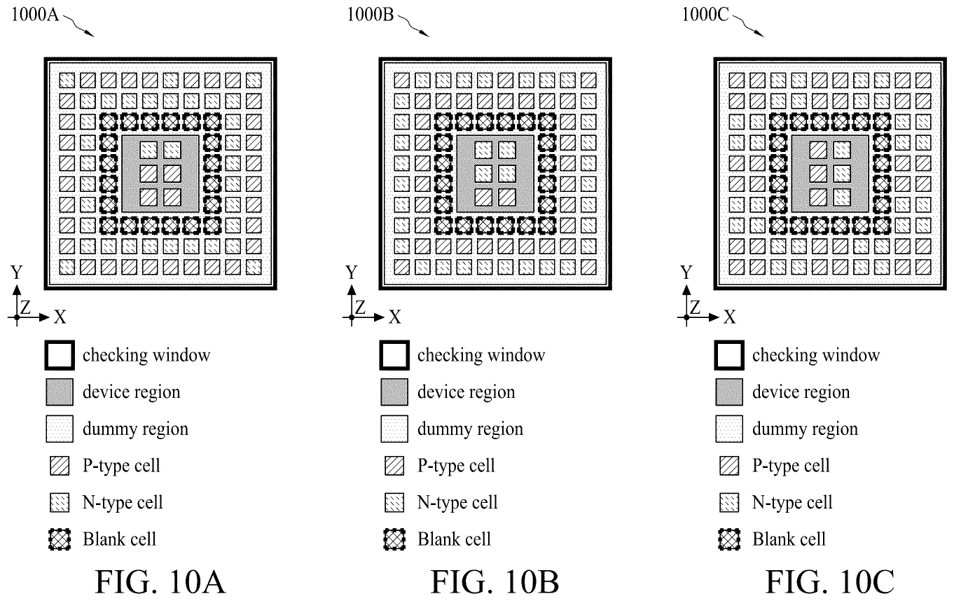

In the above embodiments described above with reference to FIGS. 3A-9F, cells (i.e., P-type cells 302, N-type cells 304, and blank cells 306) of the sub-regions are in a twelve by twelve (row by column) arrangement. In some other implementations, the cells (i.e., P-type cells 302, N-type cells 304, and blank cells 306) of the sub-regions may have other arrangements. For example, FIGS. 10A-10C illustrate sub-regions 1000A, 1000B, and 1000C having cells in a ten by ten (row by column) arrangement. Differences between the sub-regions 1000A, 1000B, and 1000C and the sub-regions described above are reflected by the figures, and repeated description is omitted for reason of simplicity.

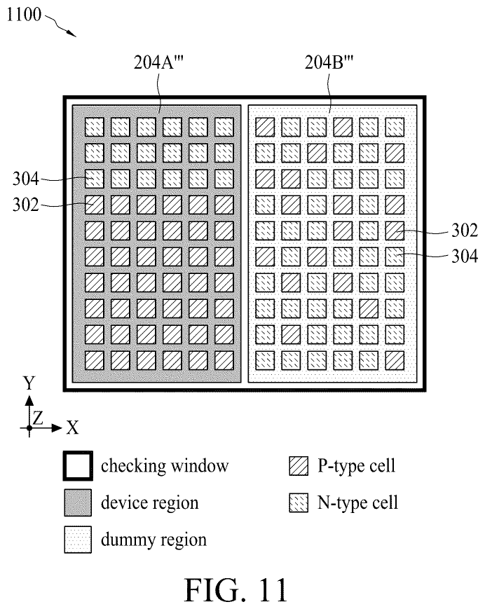

In the above embodiments described above with reference to FIGS. 2B-10C, in the top view, the dummy region (e.g., 204B) surrounds the device region (e.g., 204A). In some other alternative embodiments, the dummy region may be placed laterally adjacent the device region. For example, FIG. 11 illustrates a sub-region 1100 including a device region 204A′″ and a dummy region 204B′″ placed laterally adjacent device region 204A′″. The total number of N-type cells 304 of the sub-region 1100 is equal to the total number of P-type cells 302 of the sub-region 1100. In an illustrated embodiment, within the sub-region 1100, the number P1 of the functional P-type cells 302 is greater than the number N1 of the functional N-type cells 304, and the number P2 of the dummy P-type cells 302 is less than the number N2 of the dummy N-type cells 304. In another embodiment, within the sub-region 1100, the number P1 of the functional P-type cells 302 is less than the number N1 of the functional N-type cells 304, and the number P2 of the dummy P-type cells 302 is greater than the number N2 of the dummy N-type cells 304. In another embodiment, within the sub-region 1100, the number P1 of the functional P-type cells 302 is equal to the number N1 of the functional N-type cells 304, and the number P2 of the dummy P-type cells 302 is equal to the number N2 of the dummy N-type cells 304. The ratio of the number M of the blank cells 306 in the dummy region of the sub-region 1100 to the total number (i.e., N1+N2+P1+P2) of the sub-region 1100 is in a range between about 0 and about 45% in a way similar to the embodiments described above with reference to FIGS. 3A-10C. The alternative embodiment represented by FIG. 11 is appliable to the embodiments described above with reference to FIGS. 3A-10C.

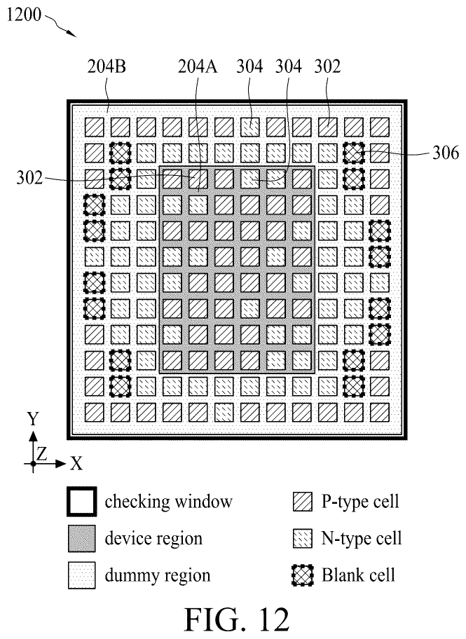

In the above embodiments described above with reference to FIGS. 2B-11, for sub-regions (e.g., 204) include blank cells 306, the blank cells 306 in the dummy region (e.g., 204B) are disposed immediately adjacent to the device region (e.g., 204A). In some other alternative embodiments, the blank cells 306 may also be randomly placed. For example, the blank cells 306 in the sub-region 1200 represented by FIG. 12 are disposed between dummy N-type cells 304 and the dummy P-type cells 302. Other positions are also possible. The alternative embodiment represented by FIG. 12 is appliable to the embodiments described above with reference to FIGS. 3A-11.

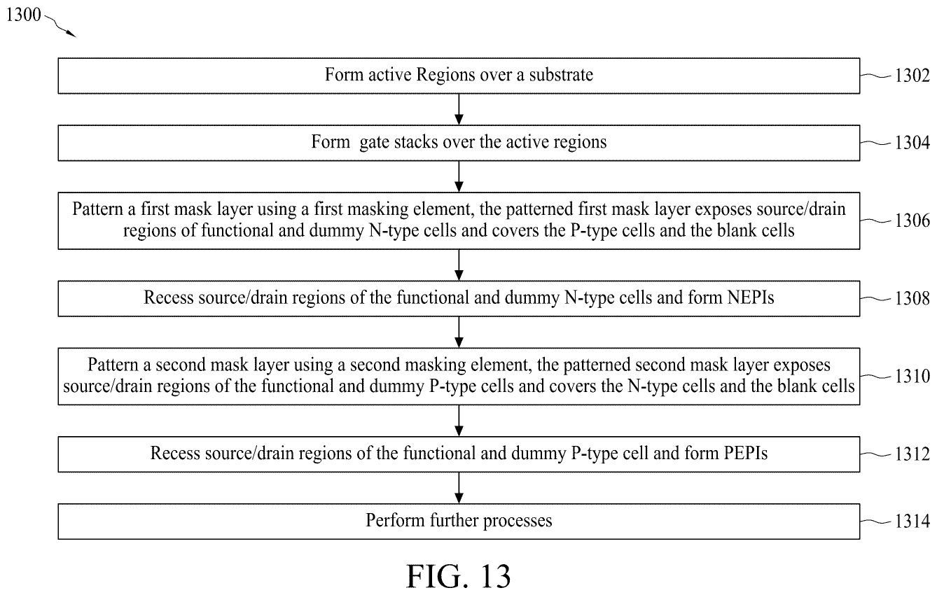

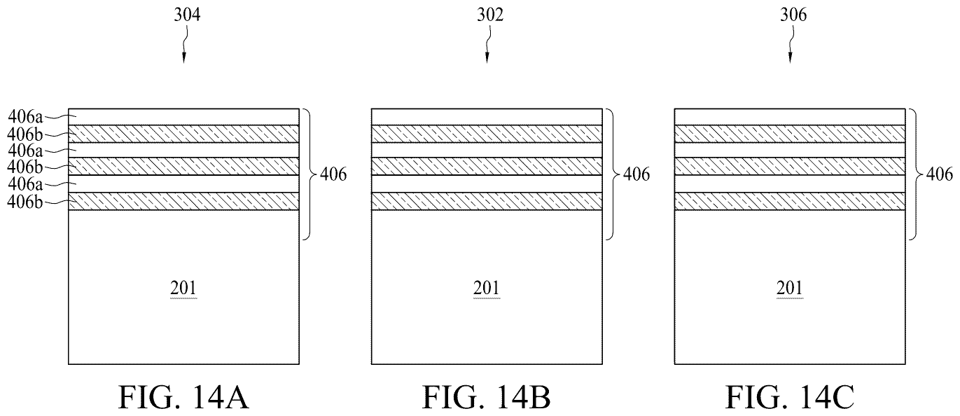

FIG. 13 illustrates a method 1300 that may be implemented to form a semiconductor structure (e.g., the semiconductor structure 200). In an embodiment, the semiconductor structure is a chip and in particular, an integrated circuit (IC) chip. The method 1300 may be implemented after a layout for the semiconductor structure 1400 has been determined as discussed above, including with respect to the method 100 of FIG. 1. The method 1300 is merely exemplary and are not intended to limit the present disclosure to what is explicitly illustrated therein. Additional steps may be provided before, during and after the method 1300, and some steps described can be replaced, eliminated, or moved around for additional embodiments of the methods. Not all steps are described herein in detail for reasons of simplicity. FIG. 13 is described with FIG. 3B above and FIGS. 14A-20A, 14B-20B, and 14C-20C below. FIGS. 14A-20A illustrate fragmentary cross-sectional views of a portion (e.g., N-type transistor in an N-type cell 304) of the semiconductor structure taken along line C-C′ as shown in FIG. 3B during various fabrication stages in the method of FIG. 13, FIGS. 14B-20B illustrate fragmentary cross-sectional views of a portion (e.g., a dummy feature in a blank cell 306) of the semiconductor structure taken along line D-D′ as shown in FIG. 3B during various fabrication stages in the method of FIG. 13, and FIGS. 14C-20C illustrate fragmentary cross-sectional views of a portion (e.g., P-type transistor in a P-type cell 302) of the semiconductor structure taken along line E-E as shown in FIG. 3B during various fabrication stages in the method of FIG. 13.

Referring to FIGS. 13 and 14A-14C, method 1300 includes a block 1302 where active regions 406 are formed over a substrate (e.g., the substrate 201). In an embodiment, as described above with reference to FIGS. 4A-4E, each of the active regions 406 includes fin having a uniform composition (e.g., silicon) in the Z-direction. In this illustrated embodiment, each of the active regions 406 includes a vertical stack of alternating channel layers 406a interleaved by sacrificial layers 406b and a top portion of the substrate 201. Each channel layer 406a may include a semiconductor material such as, silicon, germanium, silicon carbide, silicon germanium, GeSn, SiGeSn, SiGeCSn, other suitable semiconductor materials, or combinations thereof, while each sacrificial layer 406b has a composition different from that of the channel layer 406a. In an embodiment, the channel layer 406a includes silicon (Si), the sacrificial layer 406b includes silicon germanium (SiGe). The channel layers 406a and the sacrificial layers 406b may be epitaxially deposited on the substrate 201 using molecular beam epitaxy (MBE), vapor-phase epitaxy (VPE), ultra-high vacuum CVD (UHV-CVD), and/or other suitable epitaxial growth processes. In some examples, each of the active regions 406 may include a total of three to ten pairs of alternating sacrificial layers 406b and channel layers 406a; of course, other configurations may also be applicable depending upon specific design requirements. Two adjacent active regions 406 may be isolated by an isolation feature (e.g., shallow trench isolation (STI) or field oxide (FOX)).

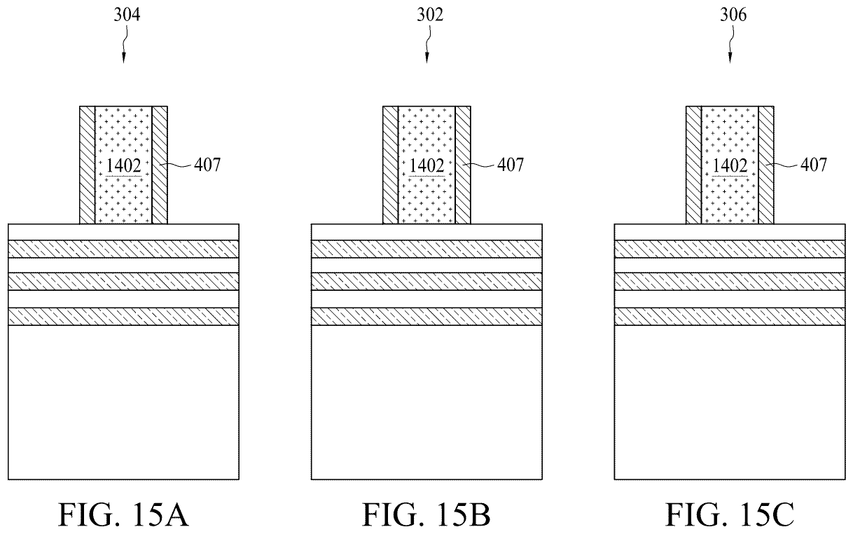

Referring to FIGS. 13 and 15A-15C, method 1300 includes a block 1304 where gate stacks 1402 are formed over the active regions 406. Each gate stack 1402 may include a dummy dielectric layer (e.g., silicon oxide) and a dummy gate electrode (e.g., polysilicon) disposed over the dummy dielectric layer. The gate stack 1402 may also include gate-top hard mask layer (e.g., SiN) over the dummy gate electrode. Gate spacers 407 are formed to extend along sidewalls of the dummy gate stacks 1402. The gate stacks 1402 may be replaced by the gate structures 404 in subsequent fabrication processes.

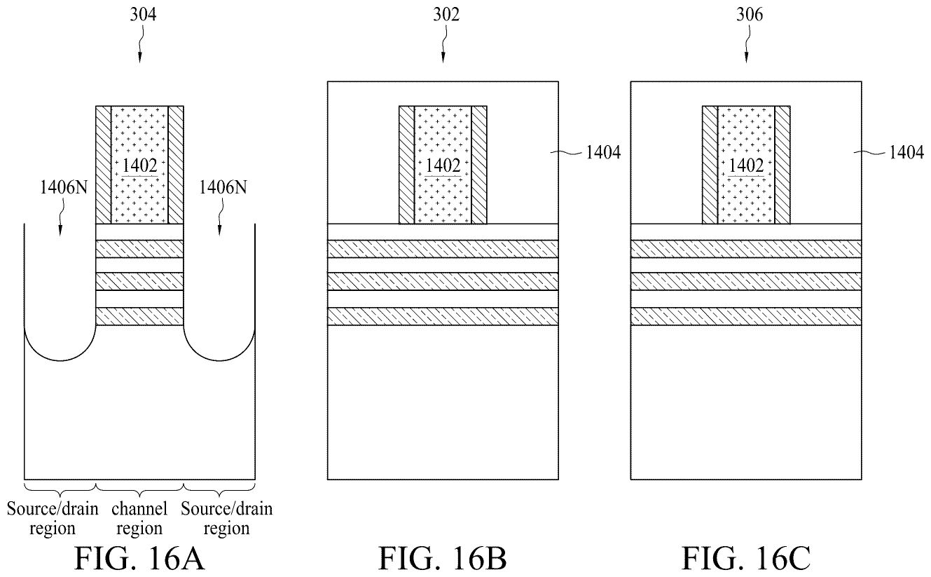

Referring to FIGS. 13 and 16A-16C, method 1300 includes a block 1306 where a first mask layer 1404 is formed over the substrate 201 and patterned using a first masking element to form openings 1406N exposing source/drain regions of the N-type cells 304. The first masking element may be designed during the layout design process described with reference to FIG. 1. The first mask layer 1404 may be patterned using a combination of lithography and etch steps. While using the patterned first mask layer 1404 as an etch mask, an etching process is performed to recess source/drain regions of the active regions 406 of the N-type cells 304 to form openings 1406N. The number of openings 1406N is a function of the open ratio of the first masking element. As illustrated by FIGS. 16B-16C, source/drain regions of P-type cells 302 and the blank cells 306 are covered by the patterned first mask layer 1404.

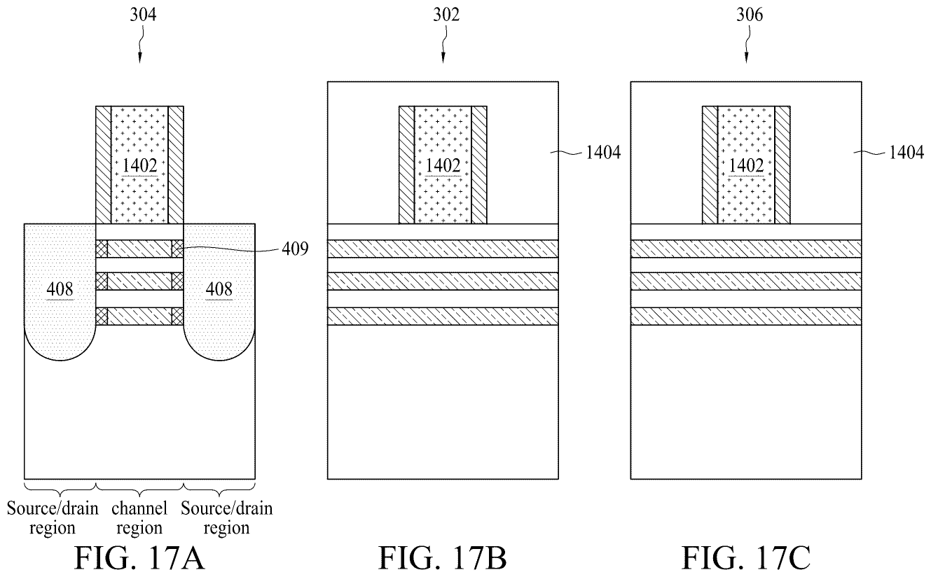

Referring to FIGS. 13 and 17A-17C, method 1300 includes a block 1308 where NEPIs 408 of the N-type cells 304 are formed in the openings 1406N. After forming the openings 1406N, inner spacer features 409 are formed between the two adjacent channel layers 406a and in direct contact with sacrificial layers 406b in the channel regions of the N-type cells 304. The inner spacer features 409 may include silicon nitride, silicon oxycarbonitride, silicon carbonitride, silicon oxide, silicon oxycarbide, silicon carbide, or silico oxynitride. NEPIs 408 are then formed in the openings 1406N. Exemplary NEPIs 408 may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. The patterned first mask layer 1404 may be selectively removed after the forming of the NEPIs 408.

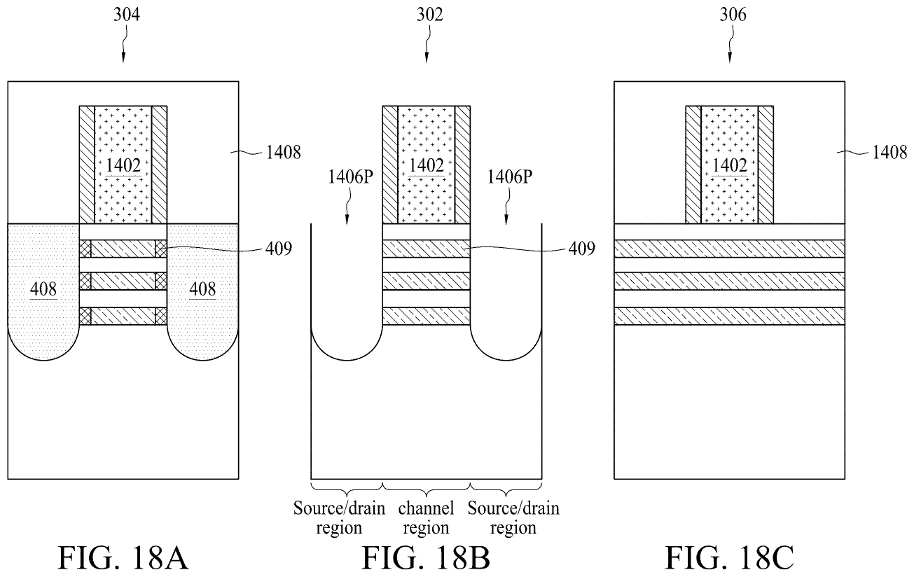

Referring to FIGS. 13 and 18A-18C, method 1300 includes a block 1310 where a second mask layer 1408 is formed over the substrate and patterned using a second masking element to form openings 1406P exposing source/drain regions of the P-type cells 302. The second masking element may be designed during the layout design process described with reference to FIG. 1. The second mask layer 1408 may be patterned using a combination of lithography and etch steps. While using the patterned second mask layer 1408 as an etch mask, an etching process is performed to recess source/drain regions of the active regions 406 of the P-type cells 302 to form openings 1406P. The number of openings 1406P is a function of the open ratio of the second masking element. As illustrated by FIGS. 18B-18C, NEPIs 408 and source/drain regions of the blank cells 306 are covered by the patterned second mask layer 1408.

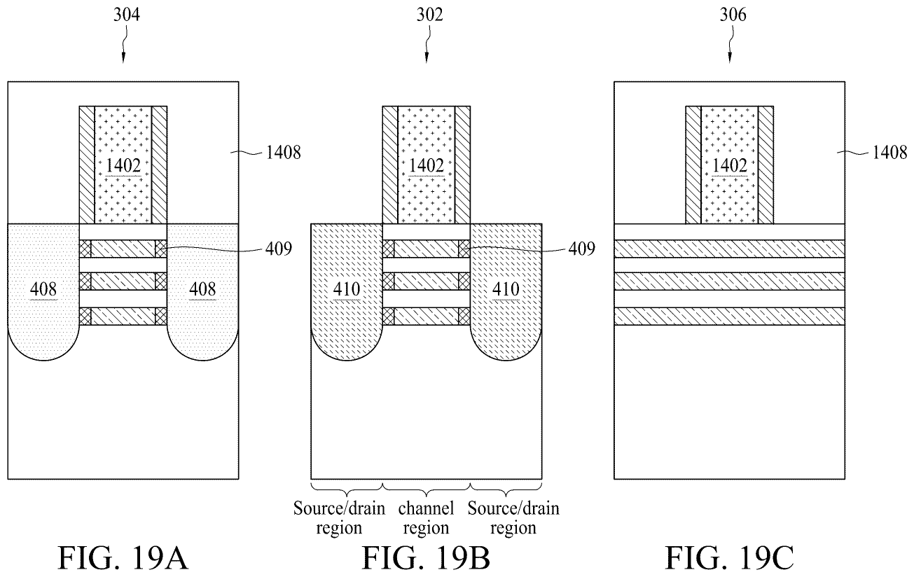

Referring to FIGS. 13 and 19A-19C, method 1300 includes a block 1312 where PEPIs 410 of the P-type cells 302 are formed in the openings 1406P. After forming the openings 1406P, inner spacer features 409 are formed between the two adjacent channel layers 406a and in direct contact with sacrificial layers 406b in the channel regions of the P-type cells 302. PEPIs 410 are then formed in the openings 1406P. Exemplary PEPIs 410 may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. The patterned second mask layer 1408 may be selectively removed after the forming of the PEPIs 410.

Referring to FIGS. 13 and 20A-20C, method 1300 includes a block 1314 where further processes are performed. Such further processes may include forming the dielectric structure 412, selectively removing the gate stacks 1402 and the sacrificial layers 406b in the channel regions, and forming the gate structures 404. As represented by FIG. 20C, since the source/drain regions of the blank cells 306 are not recessed to form openings for forming NEPIs or PEPIs, the source/drain regions of the blank cells 306 include a vertical stack of alternating channel layers 406a (e.g., silicon) and sacrificial layers 406b (e.g., silicon germanium), and the source/drain regions (including the sacrificial layers 406b) of the blank cells 306 are in direct contact with the gate structures 404. Such further processes may also include forming gate vias, source/drain contacts, and metal lines over transistors of the functional N-type cells 304 and the functional P-type cells 302 to enable the proper operation of the functional transistors. The transistors of the dummy N-type cells 304 and the dummy P-type cells 302 and features of the blank cells 306 are not electrically connected.

FIG. 21 is a block diagram of a hardware system 2100 for implementing the methods and layout embodiments described with references to FIGS. 1-20C in accordance with some embodiments. The system 2100 includes at least one processor 2102, a network interface 2104, an input and output (I/O) device 2106, a storage 2108, a memory 2112, and a bus 2110. The bus 2110 couples the network interface 2104, the I/O device 2106, the storage 2108 and the memory 2112 to the processor 2102.

In some embodiments, the memory 2112 includes a random-access memory (RAM) and/or other volatile storage device and/or read only memory (ROM) and/or other non-volatile storage device. The memory 2112 includes a kernel and user space, configured to store program instructions to be executed by the processor 2102 and data accessed by the program instructions.

In some embodiments, the network interface 2104 is configured to access program instructions and data accessed by the program instructions stored remotely through a network. The I/O device 2106 includes an input device and an output device configured for enabling user interaction with the system 2100. The input device comprises, for example, a keyboard, a mouse, etc. The output device comprises, for example, a display, a printer, etc. The storage device 2108 is configured for storing program instructions and data accessed by the program instructions. The storage device 2108 comprises, for example, a magnetic disk and an optical disk.

In some embodiments, when executing the program instructions, the processor 2102 is configured to perform the method 100 and/or provide the layouts described above. In some embodiments, the program instructions are stored in a non-transitory computer readable recording medium such as one or more optical disks, hard disks and non-volatile memory devices. In some embodiments, a file containing the layouts described above is stored in a non-transitory computer-readable storage medium.

Based on the above descriptions, it can be seen that the present disclosure offers advantages. It is understood, however, that other embodiments may offer additional advantages, and not all advantages are necessarily disclosed herein, and that no particular advantage is required for all embodiments. For example, the present disclosure provides for systems, structures, layouts and methods that allow for a chip to have an improved NPEI critical dimension in terms of CD value and/or uniformity (CDU). N-type dummy cells and blank cells in dummy region of a semiconductor structure may be selected and arranged (e.g., tuned) based on the design of the functional device region to provide for improved CD and CDU.

The present disclosure provides for many different embodiments. Semiconductor structures and methods of fabrication thereof are disclosed herein. In one exemplary aspect, the present disclosure is directed to a semiconductor structure. The semiconductor structure includes a device region comprising a number N1 of first-type device cells, wherein each first-type device cell comprises a plurality of operational N-type devices, and a number P1 of second-type device cells, wherein each second-type device cell comprises a plurality of operational P-type devices. The semiconductor structure also includes a dummy region adjacent the device region and comprising a number N2 of first-type dummy cells, wherein each first-type dummy cell comprises a plurality of non-operational N-type devices, and a number P2 of second-type dummy cells, wherein each second-type dummy cell comprises a plurality of non-operational P-type devices, wherein N1, P1, N2, P2 are integers no less than 0, and a sum of the number N1 and the number N2 is substantially equal to a sum of the number P1 and the number P2.

In some embodiments, the dummy region may also include a number of third-type dummy cells, wherein each third-type dummy cell comprises a non-operational gate structure over a fin-shaped active region, and wherein the fin-shaped active region extends lengthwise along a first direction and has a uniform composition along the first direction. In some embodiments, the plurality of operational N-type devices comprise operational N-type transistors, each of the operational N-type transistors may include a channel region over a substrate, n-type source/drain features coupled to the channel region, and an operational gate structure over the channel region. In some embodiments, the channel region may include a plurality of nanostructures, and the operational gate structure wraps around and over each of the plurality of nanostructures. In some embodiments, the plurality of non-operational N-type devices may include non-operational N-type transistors, each of the non-operational N-type transistors may include a channel region over a substrate, n-type source/drain features coupled to the channel region, and a non-operational gate structure over the channel region. In some embodiments, the channel region; a plurality of nanostructures, and the non-operational gate structure wraps around and over each of the plurality of nanostructures. In some embodiments, the number N1 is greater than the number P1, and the number N2 is less than the number P2. In some embodiments, when viewed from top, the first-type dummy cells are spaced apart from the device region by the second-type dummy cells. In some embodiments, the dummy region may also include a number M of third-type dummy cells, wherein each third-type dummy cell comprises a non-operational gate structure over a fin-shaped active region, wherein the fin-shaped active region extends lengthwise along a first direction and has a uniform composition along the first direction, M is a positive integer, and a ratio of the number M to a total number of the number N1, the number P1, the number N2, and the number P2 is less than 45%. In some embodiments, when viewed from top, the third-type dummy cells are disposed between the device region and the second-type dummy cells.

In another exemplary aspect, the present disclosure is directed to a semiconductor structure. The semiconductor structure includes a first channel region over a substrate, a doped first epitaxial feature coupled to the first channel region, a first gate structure over the first channel region, a second channel region over the substrate, a second epitaxial feature coupled to the second channel region, and a second gate structure over the second channel region, where the second epitaxial feature includes a vertical stack of alternating first semiconductor layers and second semiconductor layers.

In some embodiments, the semiconductor structure may also include a third channel region over the substrate, a doped third epitaxial feature coupled to the third channel region, and a third gate structure over the third channel region. In some embodiments, the doped first epitaxial feature and the doped third epitaxial feature have a same dopant polarity. In some embodiments, the doped first epitaxial feature and the doped third epitaxial feature have different dopant polarities. In some embodiments, each of the first channel region, the second channel region and the third channel region may include a plurality of the first semiconductor layers. In some embodiments, the second gate structure is in direct contact with the second epitaxial feature.

In another exemplary aspect, the present disclosure is directed to a method. The method includes provide a substrate having a first device region, a second device region, a first dummy region and a second dummy region adjacent the first and second device regions, forming a first active region, a second active region, a third active region, and a fourth active region in the first dummy region, second dummy region, first device region, and first dummy region, respectively, forming gate structures extending over the first active region, second active region, third active region, and fourth active region, providing a first masking element with a first set of openings over the first dummy region and the first device region, wherein the first masking element covers the second dummy region and the second device region, growing first epitaxial features having a first dopant type in the first dummy region and the first device region while providing the first masking element, providing a second masking element with a second set of openings over the second dummy region and the second device region, wherein the second masking element covers the first dummy region and the first device region, and growing second epitaxial features having a second dopant type in the second dummy region and the second device region while the providing the second masking element.

In some embodiments, the first device region may include a number of functional N-type devices, the second device region may include a number of functional P-type devices, the first dummy region may include a number of non-functional N-type devices, the second dummy region may include a number of non-functional P-type devices, and a total number of the functional P-type devices and the non-functional P-type devices is equal to a total number of the functional N-type devices and the non-functional N-type devices. In some embodiments, each of the first, second, third, and fourth active regions may include a stack of alternating channel layers and sacrificial layers over the substrate, and the method may also include, after growing the first and second epitaxial features, selectively removing the gate structures to form gate trenches, selectively removing portions of the sacrificial layers disposed directly under the gate structures to form gate openings, and forming gate stacks in the gate trenches and gate openings. In some embodiments, a gate stack of the gate stacks in the second dummy region is in direct contact with the sacrificial layers.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor structure, comprising:
a device region comprising:
a number N1 of first-type device cells, wherein each first-type device cell comprises a plurality of operational N-type devices, and
a number P1 of second-type device cells, wherein each second-type device cell comprises a plurality of operational P-type devices; and
a dummy region adjacent the device region and comprising:
a number N2 of first-type dummy cells, wherein each first-type dummy cell comprises a plurality of non-operational N-type devices, and
a number P2 of second-type dummy cells, wherein each second-type dummy cell comprises a plurality of non-operational P-type devices,
wherein N1, P1, N2, P2 are integers no less than 0, and a sum of the number N1 and the number N2 is substantially equal to a sum of the number P1 and the number P2.

2. The semiconductor structure of claim 1, wherein the dummy region further comprises:
a number of third-type dummy cells, wherein each third-type dummy cell comprises a non-operational gate structure over a fin-shaped active region, and wherein the fin-shaped active region extends lengthwise along a first direction and has a uniform composition along the first direction.

3. The semiconductor structure of claim 1, wherein the plurality of operational N-type devices comprise operational N-type transistors, each of the operational N-type transistors comprises:
a channel region over a substrate;
n-type source/drain features coupled to the channel region; and
an operational gate structure over the channel region.

4. The semiconductor structure of claim 3, wherein the channel region comprises a plurality of nanostructures, and the operational gate structure wraps around and over each of the plurality of nanostructures.

5. The semiconductor structure of claim 1, wherein the plurality of non-operational N-type devices comprise non-operational N-type transistors, each of the non-operational N-type transistors comprises:
a channel region over a substrate;
n-type source/drain features coupled to the channel region; and
a non-operational gate structure over the channel region.

6. The semiconductor structure of claim 5, wherein the channel region comprises a plurality of nanostructures, and the non-operational gate structure wraps around and over each of the plurality of nanostructures.

7. The semiconductor structure of claim 1, wherein the number N1 is greater than the number P1, and the number N2 is less than the number P2.

8. The semiconductor structure of claim 7, wherein, when viewed from top, the first-type dummy cells are spaced apart from the device region by the second-type dummy cells.

9. The semiconductor structure of claim 7, wherein the dummy region further comprises:
a number M of third-type dummy cells, wherein each third-type dummy cell comprises a non-operational gate structure over a fin-shaped active region, wherein the fin-shaped active region extends lengthwise along a first direction and has a uniform composition along the first direction,
wherein M is a positive integer, and a ratio of the number M to a total number of the number N1, the number P1, the number N2, and the number P2 is less than 45%.

10. The semiconductor structure of claim 9, wherein, when viewed from top, the third-type dummy cells are disposed between the device region and the second-type dummy cells.

11. A semiconductor structure, comprising:
a first channel region over a substrate;
a doped first epitaxial feature coupled to the first channel region;
a first gate structure over the first channel region;
a second channel region over the substrate;
a second epitaxial feature coupled to the second channel region; and
a second gate structure over the second channel region,
wherein the second epitaxial feature comprises a vertical stack of alternating first semiconductor layers and second semiconductor layers.

12. The semiconductor structure of claim 11, further comprising:
a third channel region over the substrate;
a doped third epitaxial feature coupled to the third channel region; and
a third gate structure over the third channel region.

13. The semiconductor structure of claim 12, wherein the doped first epitaxial feature and the doped third epitaxial feature have a same dopant polarity.

14. The semiconductor structure of claim 12, wherein the doped first epitaxial feature and the doped third epitaxial feature have different dopant polarities.

15. The semiconductor structure of claim 12, wherein each of the first channel region, the second channel region and the third channel region comprises a plurality of the first semiconductor layers.

16. The semiconductor structure of claim 11, wherein the second gate structure is in direct contact with the second epitaxial feature.

17. A method, comprising:
provide a substrate having a first device region, a second device region, a first dummy region and a second dummy region adjacent the first and second device regions;
forming a first active region, a second active region, a third active region, and a fourth active region in the first dummy region, second dummy region, first device region, and first dummy region, respectively;
forming gate structures extending over the first active region, second active region, third active region, and fourth active region;
providing a first masking element with a first set of openings over the first dummy region and the first device region, wherein the first masking element covers the second dummy region and the second device region;
growing first epitaxial features having a first dopant type in the first dummy region and the first device region while providing the first masking element;
providing a second masking element with a second set of openings over the second dummy region and the second device region, wherein the second masking element covers the first dummy region and the first device region; and
growing second epitaxial features having a second dopant type in the second dummy region and the second device region while the providing the second masking element.

18. The method of claim 17, wherein the first device region comprises a number of functional N-type devices, the second device region comprises a number of functional P-type devices, the first dummy region comprises a number of non-functional N-type devices, the second dummy region comprises a number of non-functional P-type devices, and a total number of the functional P-type devices and the non-functional P-type devices is equal to a total number of the functional N-type devices and the non-functional N-type devices.

19. The method of claim 17, wherein each of the first, second, third, and fourth active regions comprises a stack of alternating channel layers and sacrificial layers over the substrate, and the method further comprising:
after growing the first and second epitaxial features, selectively removing the gate structures to form gate trenches;
selectively removing portions of the sacrificial layers disposed directly under the gate structures to form gate openings; and
forming gate stacks in the gate trenches and gate openings.

20. The method of claim 19, wherein a gate stack of the gate stacks in the second dummy region is in direct contact with the sacrificial layers.
